(19) United States
(12) Patent Application Publication
(10) Pub. No.: US 2008/0142899 A1
(43) Pub. Date: Jun. 19, 2008

(54) RADIATION IMMUNITY OF INTEGRATED CIRCUITS USING BACKSIDE DIE CONTACT AND ELECTRICALLY CONDUCTIVE LAYERS

(75) Inventors: Wesley H. Morris, Austin, TX (US); Jon Gwin, San Antonio, TX (US); Rex Lowther, Palm Bay, FL (US)

Correspondence Address: ZAGORIN O'BRIEN GRAHAM LLP, 7600B NORTH CAPITAL OF TEXAS HIGHWAY, SUITE 350, AUSTIN, TX, 78731, US

(73) Assignee: SILICON SPACE TECHNOLOGY CORPORATION, Austin, TX (US)

(21) Appl. No.: 11/833,989

(22) Filed: Aug. 4, 2007

Related U.S. Application Data
(60) Provisional application No. 60/835,688, filed on Aug. 4, 2006.

(51) Int. Cl. H01L 29/36; H01L 21/223

(52) U.S. Cl. 257/371; 438/526; 257/369; 257/E29.109; 257/E21.143

(57) ABSTRACT

Radiation hardened integrated circuit devices may be fabricated using conventional designs and process, but including specialized structures to reduce or eliminate detrimental effects caused by various forms of radiation. An exemplary BGR structure includes a high-dose buried guard ring (HBGR) layer which is contacted to ground through the backside of the wafer or circuit die, thus forming a Backside BGR (BBGR) structure. In certain embodiments, the starting wafer may be highly doped to reduce the resistance from the HBGR to the back of the wafer, which is then further contacted to ground through the package. The performance of such devices may be further improved by using an electrically conductive adhesive to attach the die and to electrically connect the silicon substrate region to the package's conductive header, substrate, or die attach pad, which in turn is typically connected to one or more package pins/balls.

### CROSS-REFERENCE TO RELATED APPLICATION(S)

This application claims the benefit under 35 U.S.C. § 119(e) of U.S. Provisional Application No. 60/835,688, filed Aug. 4, 2006, which application is incorporated herein by reference in its entirety.

### STATEMENT REGARDING FEDERALLY SPONSORED RESEARCH OR DEVELOPMENT

This invention was made with Government support under Contract No. FA9453-04-C-0409 awarded by Air Force Research Laboratory. The Government has certain rights in the invention.

### BACKGROUND

1. Field of the Invention

The present invention relates to integrated circuits, and particularly to integrated circuits providing partial and/or complete immunity to failure modes associated with radiation exposure.

2. Description of the Related Art

The high radiation environments, including the upper atmosphere, near-earth orbit, outer space, and certain terrestrial environments (e.g., proximity to devices producing significant amounts of radiation) provide the most hostile environments for reliable operation of microelectronic solid-state devices. Exposure to radiation causes electrical degradation of both transistors and circuit-isolation elements, which can lead to sporadic device behavior and/or complete destructive failure of integrated circuits (ICs). Because of the complexities of designing and fabricating integrated circuits tolerant of radiation environments, during the 1980s a number of large commercial semiconductor companies began to specialize in the production of radiation-hardened ICs, primarily for military and aerospace systems.

At the same time, the high manufacturing costs of non-radiation-hardened commercial ICs has generally been offset by progress in high volume production, growing from less than $40B to more than $200B in 2004. To remain competitive, commercial IC manufacturers have deployed new state-of-the art silicon IC manufacturing facilities every 3-5 years.

The more limited low-volume demand for radiation-hardened ICs cannot justify the expense of dedicated leading-edge manufacturing facilities, despite the very attractive margins in the military and aerospace electronics market. These financial constraints have severely limited the ability of radiation-hardened IC suppliers to utilize leading-edge IC manufacturing technology. Consequently, the number of companies producing radiation-hardened IC components has been dramatically reduced, and their capabilities have fallen far behind those of the commercial sector.

During the 1990s, the combination of rising costs for new IC manufacturing facilities, military budget reductions, and a dwindling number of suppliers widened the technological disparity between commercial and radiation-hardened microelectronics. Commercial and military satellite manufacturers attempting to bridge this gap were forced to employ a new concept called “COTS” (commercial off-the-shelf) to procure the high-performance ICs required for building their electronic platforms.

The COTS approach uses extensive laboratory testing of commodity (unhardened) commercial ICs to screen and “qualify” them for applications where they are likely to be exposed to damaging radiation. COTS was considered the only practical solution to obtain space-qualified high-performance ICs. Despite greatly diluted radiation standards, qualified product could not reliably be found using COTS. Therefore, those few nominally acceptable ICs typically offered no significant cost savings. Satellites manufactured using COTS ICs have suffered significant reductions in capability and mission lifetime due to destructive radiation exposure. The advancing miniaturization of CMOS technology increases sensitivity to certain forms of radiation, further widening the gap between COTS capabilities and space electronics market requirements. After more than ten years of system failures, the COTS approach has failed to provide a viable solution for the supply of radiation-hardened ICs.

Accordingly, it is desirable to bring high-performance and cost-effective radiation-hardened integrated circuits (RHICs) to military, aerospace, and certain terrestrial electronics markets using the readily accessible leading-edge infrastructure of high-volume commercial microelectronics manufacturers. More specifically, it is further desirable to systematically address at the silicon process level each of the degradation mechanisms caused by radiation and to thereby develop new radiation hardened solutions that can be integrated into commercial microelectronic fabrication processes without impacting significantly the commercial baseline electrical spice parameters. This methodology offers the promise of circuit intellectual property (IP) re-use which would create new and distinct radiation hard circuit products from existing commercial circuit designs while avoiding costly circuit redesigns.

### SUMMARY

In general, the invention is directed to radiation hardened integrated circuit devices and techniques for radiation hardening integrated circuit devices. However, the invention is defined by the appended claims, and nothing in this section shall be taken as limiting those claims.

It has been discovered that semiconductor devices can be fabricated using conventional designs and process but including specialized structures to reduce or eliminate detrimental effects caused by various forms of radiation. Such semiconductor devices can include the one or more parasitic isolation devices and/or buried guard ring structures disclosed in the present application. The introduction of design and/or process steps to accommodate these novel structures is compatible with conventional CMOS fabrication processes, and can therefore be accomplished at relatively low cost and with relative simplicity.

For example, some devices may incorporate a BGR structure in which a vertical conductor (e.g., a vertical implant region, metallization, or the like) generally connects a high-dose buried guard ring (HBGR) layer to a surface terminal of the die (e.g., a p−well contact region), which can be coupled to ground. By so doing, the HBGR layer and the vertical conductor structure together form the BGR structure.

Rather than contact the HBGR through a set of implants (or other conductive pathway) to the surface as described above, the HBGR layer can be contacted to ground through the backside of the wafer or circuit die, thus forming a Backside BGR (BBGR) structure. In certain embodiments, the starting wafer may be highly doped to reduce the resistance from the HBGR to the back of the wafer, which is then further contacted (particularly to ground) through the package. The reduced resistance can be accomplished, for example, using an epitaxial P− layer (i.e., lightly-doped P-type layer) grown on a P+ substrate wafer with enough thickness to accommodate the NFET and PFET devices of the circuit without interference from the initial P+ bulk wafer doping. Various alternative techniques can be used to conductively couple the HBGR to the backside of the die including, for example, vertical implant regions between the HBGR and the backside of the die.

The performance of such devices is further improved through the use of an electrically conductive adhesive between the backside of the die and certain portions of the package to electrically connect the silicon region to the package's conductive header, substrate, or die attach pad, which in turn is typically connected to one or more package pins/balls. In some embodiments, the backside of the die can undergo preparation steps before application of the adhesive, such as lapping, deglazing, die thinning, backside surface metallization, etc. Various different electrically conductive adhesives can be used including metallic pastes, conductive epoxies, conductive thermoplastics, and cyanate esters. Moreover, these techniques can be used with various different types of packages.

The invention in several aspects is suitable for semiconductor devices, integrated circuits, for methods for operating such devices or integrated circuits, for methods of making semiconductor device products, and for computer readable media encodings of such integrated circuits or products, all as described herein in greater detail and as set forth in the appended claims. The described techniques, structures, and methods may be used alone or in combination with one another.

The foregoing is a summary and thus contains, by necessity, simplifications, generalizations and omissions of detail. Consequently, those skilled in the art will appreciate that the foregoing summary is illustrative only and that it is not intended to be in any way limiting of the invention. As will also be apparent to one skilled in the art, the operations disclosed herein may be implemented in a number of ways, and such changes and modifications may be made without departing from this invention and its broader aspects. Other aspects, inventive features, and advantages of the present invention, as defined solely by the claims, may be apparent from the detailed description set forth below.

### BRIEF DESCRIPTION OF THE DRAWINGS

A more complete understanding of the present invention and advantages thereof may be acquired by referring to the following description and the accompanying drawings, in which like reference numbers indicate like or similar features.

FIGS. 1A-1H illustrate simplified block diagrams of transistor structures utilizing channel region extensions.

FIG. 2 shows a cross-section diagram of a CMOS inverter formed on a p− substrate.

FIG. 3 illustrates a simplified block diagram of an inverter structure utilizing several techniques and devices useful for the present invention.

FIG. 4 illustrates a simplified block diagram of an inverter structure utilizing additional techniques and devices useful for the present invention.

FIG. 5 illustrates a simplified block diagram of an inverter structure utilizing still other techniques and devices useful for the present invention.

FIGS. 6A-6B illustrate additional embodiments of the structure illustrated in FIG. 3.

FIGS. 7A-7C illustrate various embodiments of a BGR structure.

FIGS. 8A-8E illustrate still other embodiments of a BGR structure.

FIGS. 9A-9C illustrate 2D and 1D simulations of the doping profiles of exemplary BGR structures.

FIG. 10 provides a typical current vs. voltage (I-V) trace illustrating latch-up.

FIG. 11 illustrates I-V traces showing latch-up improvement associated with use of a BGR structure.

FIGS. 12-13 illustrate 1D simulations of doping profiles corresponding to BGR structures showing respectively an HDBL below a p+ diffusion in an n−well, and below a p+ diffusion in a p−well, for an exemplary process.

FIG. 14 depicts boron doping profiles for three structures of interest.

FIG. 15 depicts an embodiment of a backside BGR structure.

FIG. 16 depicts another embodiment of a backside BGR structure.

FIG. 17 depicts yet another embodiment of a backside BGR structure.

FIG. 18 depicts an embodiment utilizing bipolar BGR structures.

FIG. 19 depicts an embodiment utilizing segmented BGR structures.

### DETAILED DESCRIPTION

The following sets forth a detailed description of at least the best contemplated mode for carrying out the one or more devices and/or processes described herein. The description is intended to be illustrative and should not be taken to be limiting.

The devices and techniques described in the present application can deliver a complete radiation solution, or in some cases a specialized radiation solution, by directly addressing one or more of the primary degradation radiation effects of ICs: Total Ionizing Dose (TID), Single Event Latch-up (SEL), and Single-Event Upset (SEU). Moreover, the solutions to these degradation mechanisms are accomplished at the silicon process level with modifications to existing foundry baseline process. These unique approaches can be integrated into any CMOS process flow without affecting the performance of the underlying baseline technology. These approaches can further take advantage of a variety of different IC fabrication technologies, such as silicon-on-insulator (SOI) and the like. Additionally, although the examples of the present application will focus on MOS (and particularly CMOS) implementations, it will be understood by those having ordinary skill in the art that the devices and techniques disclosed herein can be extended to other semiconductor architectures such as BiCMOS, etc.

This disclosure describes various structures and techniques that each generally provide some manner of protection from one or more of the degradation effects associated with radiation, and particularly ionizing radiation. When combined, these structures and techniques provide novel radiation hardened process isolation (RHPI) schemes. When integrated into a CMOS process silicon structure, the RHPI structures can significantly reduce the sensitivity of the silicon electrical devices to ionizing radiation, single event latch up, and single event soft error. The RHPI structures can generally be applied to any MOS or BiCMOS silicon process and will directly improve radiation hardening properties of the integrated circuit both during and after exposure to a radiation environment. Moreover, this is accomplished with little or no penalty to circuit size and or electrical performance. As such, the RHIP schemes can be used as an “add on” feature, which can be applied to existing MOS or BiCMOS process technology, improving radiation isolation properties without the need for extensive process or circuit changes. The RHPI structures enable radiation hardening of commercial digital process by leveraging existing solid state processing technology and re-use of leading edge circuit IP for the creation of radiation hardened circuit product.

Ionizing radiation occurs naturally in the form of high-energy photons or charged particles that possess enough energy to break atomic bonds and create electron-hole pairs in an absorbing material. These particles can include protons, electrons, atomic ions, and photons with energies greater than a bandgap of the absorbing material. When typical integrated circuits, such as CMOS integrated circuits, are exposed to the charged particles over a period of months or even years, the ionizing radiation can contribute to a total ionizing dose (TID). For example, as an ionizing particle passes through a MOS device, it generates one or more electron-hole pairs which can be trapped in the gate oxides and the field oxides. Electrons in the semiconductor's valence band are raised to the conduction band. A fraction of the electron-hole pairs will undergo initial recombination and cause no damage, but such recombination decreases as the electric field increases, and the electrons and holes that survive it are free to diffuse and drift within the oxide where they will be swept from the insulator, recombine, or be trapped.

Mobile electrons typically move through both gate and field oxides quickly, but the holes have a relatively low effective mobility and are easily trapped in gate oxides and field oxides. Because the trapped holes create a positive oxide charge, the resulting space-charge fields cause negative shifts in the threshold voltages of corresponding transistors. As a threshold voltage shifts negatively, a transistor biased in the off-state lets more and more current pass. If enough holes are trapped, an n-channel transistor will remain fully conducting even with zero applied gate bias, causing, for example, an enhancement-mode device to become a depletion-mode device. In many cases, the edge or field region of the device becomes depletion-mode. Should that happen, leakage currents passing around a device (or from device to device) can cause parameter degradation and, ultimately, device and circuit failure.

Ionizing radiation also boosts the interface trap density in MOS structures. Interface traps are localized electronic states close to the interface between silicon and silicon dioxide and can exchange charge with the silicon conduction and valence bands. They shift threshold voltage and can also degrade mobility by acting as scattering centers. More specifically, the increase in interface states shifts the threshold voltages in the negative direction (more depletion Vₜ) for n-channel devices and in the positive direction (more enhancement Vₜ) for p-channel devices. In addition to the positive oxide shift and the interface states shift described above with respect to n-channel and p-channel devices, threshold voltage shifts caused by ionizing radiation further affect parasitic MOS elements, giving rise, for example, to leakage currents that may cause parametric failure and/or functional failure.

Even more specialized devices can be susceptible to TID. For example, SOI transistors can also be affected by TID through charge buildup in the insulator such as a buried oxide. For partially depleted transistors, charge buildup can invert the back surface causing a source-to-drain (back-channel) leakage current. Moreover, this leakage current is relatively unaffected by gate bias. For fully-depleted transistors, there is significant sensitivity to radiation-induced oxide and interface-trap charge buildup. Positive oxide charge buildup tends to deplete the back-channel interface causing a decrease in the threshold voltage of the front-channel gate oxide and increased back-channel leakage current. Thus, a wide variety of threshold voltage instabilities can result.

Thus, the effects of ionizing radiation lead to the degradation of performance and ultimate failure of the CMOS devices. The additional radiation-induced interface states degrade the circuit performance by reducing the channel mobility, which as a result decreases channel conductance and transistor gain. Over time, the threshold voltages of the n-channel and p-channel devices may shift to such a degree where the n-channel transistors cannot be turned off and the drive capability of the p-channel transistors is not sufficient for the circuit to continue operating at the system clock rate. Such a shift in threshold voltages of either the n-channel or p-channel transistors can cause a circuit to fail.

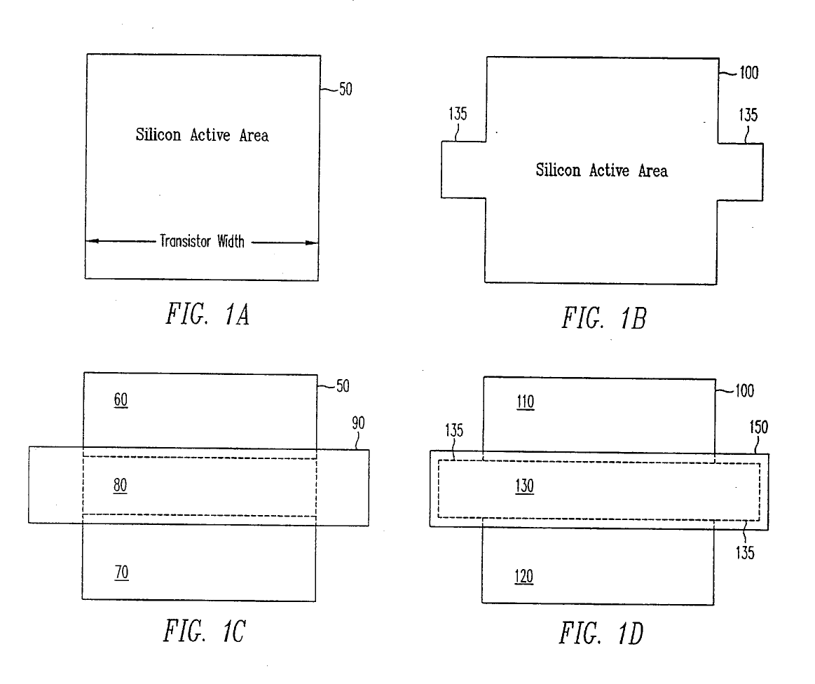

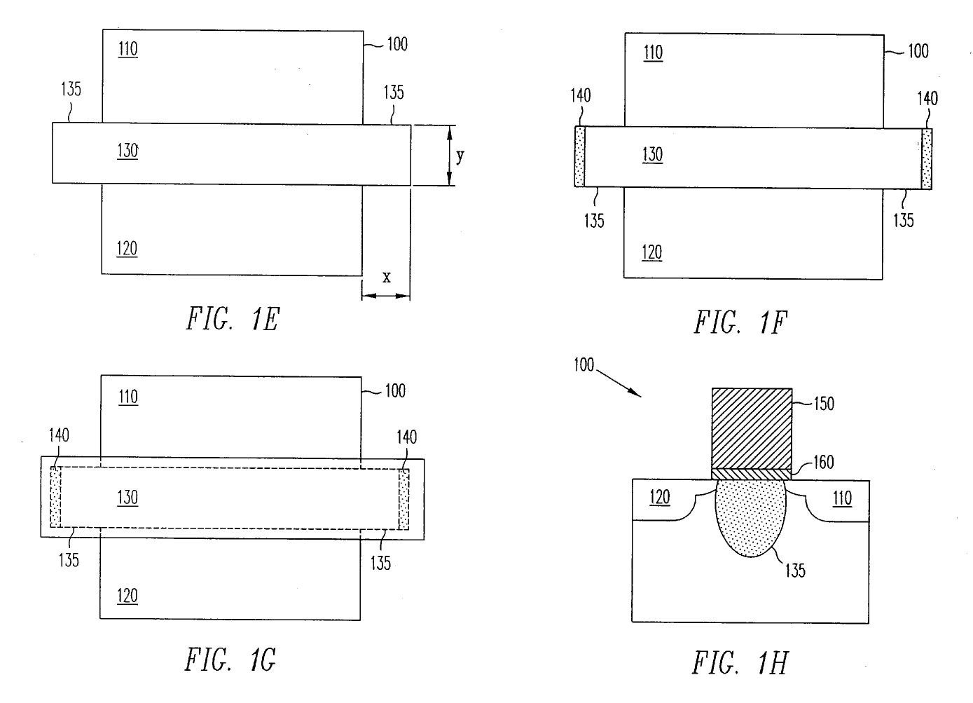

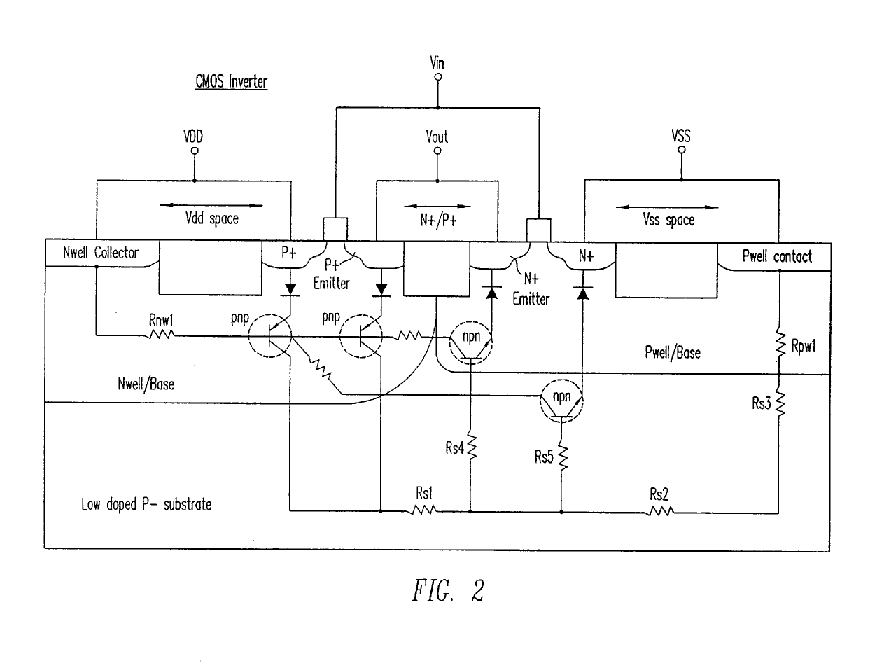

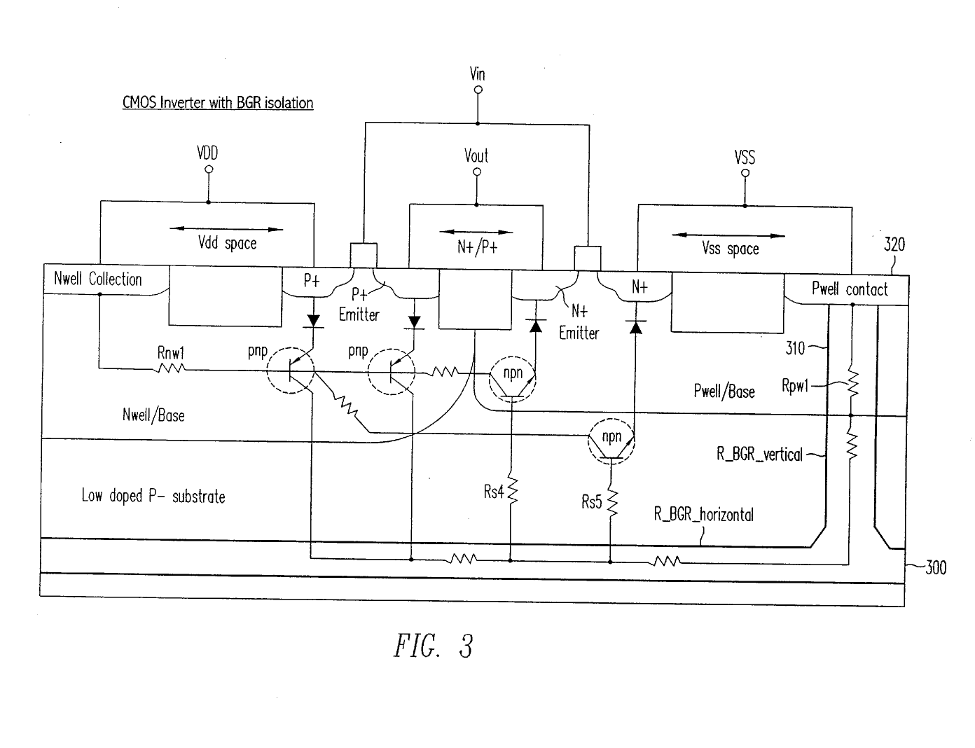

FIGS. 1A-1H illustrate one approach to addressing the parasitic effects associated with TID in a conventional MOS device. Transistor 100 (shown in FIGS. 1B and 1D-H) differs from conventional MOS devices (shown in FIGS. 1A and 1C) in that channel region 130 of transistor 100 includes two channel region extensions 135. In traditional MOS devices like transistor 50, source (60), drain (70), and channel regions (80) are typically fabricated to have approximately the same width as shown. However, as shown in FIGS. 1B and 1D-H, source region 110 and drain region 120 have approximately the same widths while channel region 130 has a greater width leading to channel region extensions 135 that extend beyond the edges of the source and drain regions, i.e., beyond the channel region's typical interfaces with each of the source and drain regions. Channel region extensions 135 are typically formed by an extension of the silicon active area from which the source, drain, and channel regions are formed, or by formation of mesa regions immediately adjacent to the channel region. Because of their role in reducing the parasitic effects associated with TID, these extended active area structures can be referred to as parasitic isolation devices (PIDs).

Each of channel region extensions 135 have a width x and a length y (FIG. 1E). Although FIGS. 1B and 1D-H illustrate channel region extensions 135 having approximately the same dimensions as each other, this need not be the case. Channel region extension length y is typically smaller than the length of polysilicon gate 150, while channel region extension width×can be selected to provide the desired device features. The increased length of the channel edge caused by the extensions, i.e., and increase from y to 2x+y, serves to increase the effective channel length of channel region 130 to a value greater than the case where the channel region terminates “flush” with source and drain regions 110 and 120. By increasing the net channel edge length, channel region extensions 135 lead to significantly reduced OFF state leakage due to the attenuation of parasitic transistor short channel effects.

In a typical implementation, the PID structure effectively increases the local channel length by more than a factor of two. The geometry of the PID provides for selective doping within specific regions 140 as shown in FIGS. 1F-1H. FIGS. 1F and 1G show top views of device 100 including channel extension impurity regions 140, typically formed along the length of channel region extensions 135. Channel extension impurity regions 140 are typically formed to have relatively high impurity concentrations, and are introduced to overlap end portions of the channel region extensions so that the impurity concentration of these end portions is increased relative to the impurity concentration of those portions of the channel region 130 located between source region 110 and drain region 120. For example, where the channel region has a p− impurity concentration, channel extension impurity regions 140 form a pair of p+ channel stops. This relatively high impurity concentration of the channel stop insures that the parasitic sidewall threshold is higher than any negative threshold shift which might be induced by ionizing radiation. These more heavily doped extension impurity regions are typically spaced apart from the endwall edges of source and drain regions 110 and 120 by respective portions of the extension regions of the same doping concentration as channel region 130 itself, so that the more heavily doped channel extension impurity regions do not form p+/n+ junctions with the source and drain regions 110 and 120. Such junctions can have very low breakdown voltages, thereby adversely effecting device performance. The extension width x is generally determined by the choice of doping ion and the manufacturing process's thermal diffusion exposure. For example, a boron doped PID structure would typically have a larger extension width x as compared to an Indium doped PID structure. Thus, extension width will typically be driven by concerns about excess back-diffusion and enhanced doping of the transistor active area. In general, either acceptor or donor impurities can be used to form channel extension impurity regions 140. Variation of impurity type, implant energy, and dose will typically provide different types and/or levels of radiation isolation improvement.

As shown in FIG. 1G, channel region extensions 135 are located below (and hidden by) gate electrode 150, which allows self aligned conventional processing to be used subsequent to PID formation. In the case of n-channel devices, the channel region extensions when combined with impurity doping can be used to prevent unwanted electrical inversion (threshold voltage depletion) of the edges (or sides) of the n-channel transistor silicon channel area. This sensitive region generally extends below the gate electrode between source region 110 and drain region 120, as illustrated in FIG. 1H which shows an end view of the device. Thus, in some embodiments, channel extension impurity regions 140 are formed to extend to a depth greater than the depths of the source and drain regions. The PID can likewise be used in p-channel transistors to prevent threshold voltage enhancement (opposite of n-channel) caused by positive charge accumulation along the active area edge of the PMOS transistor active area. Note that because the PID structure can increase the size of the transistors active area, gate capacitance may also increase. This can lead to reduced speed in operation of the transistor. To compensate for this effect, various embodiments can adjust different aspects of the device geometry. For example, in one embodiment the width of the PMOS can be increased to help reduce the gate capacitance.

Thus, the PID structure reduces or eliminates parasitic field transistor inversion which reduces or eliminates a major source of I_{off} leakage caused by charge build up at the silicon/SiO₂ (160) boundary. Moreover, the PID structure doped region provides for local minority carrier lifetime reduction, reduced sensitivity to substrate noise and body voltage effects, and enhances the transistor snap-back voltage. The PID structures described herein can be fabricated in both bulk silicon and silicon films, such as silicon-on-insulator (SOI).

Latch-up generally, and in the case of circuits in radiation environments SEL, is a serious failure mode in CMOS circuits. In the best case, latch-up results in soft failure with a loss of data or logic state. In the worst case, latch-up causes a destructive hard failure with permanent loss of the circuit. Thus, from a circuit reliability perspective, latch-up is to be avoided at all costs. As isolation widths shrink, device structures become even more susceptible to both latch-up failure modes. Prevention of both transient and destructive failures is very important in advanced CMOS IC's since most conventional CMOS technologies have largely converged on the use of p− bulk substrates. As noted above, radiation environments present special problems to CMOS circuits in that high-energy particles deposit significant electrical charge to the bulk substrate. The instantaneous appearance of static charge deposited by a high-energy particle passing through an IC can immediately induce large displacement currents on the pico-second time scale accompanied with rapid potential shifts away from initial logic states. The deposition of energy by the particle typically causes diodes to forward bias, followed by large transient injection currents which reinforce the transient upset and can cause the CMOS circuit to latch-up.

Latch-up in a conventional CMOS inverter circuit is illustrated in FIG. 2. FIG. 2 shows a cross-section diagram of a CMOS inverter formed on a p− substrate. An equivalent circuit diagram is also shown in FIG. 2 overlaid on the CMOS inverter. In CMOS technology, the basic switching circuit is an inverter formed from a complementary pair of MOS transistors, one NMOS and one PMOS. Electrical isolation is achieved by using both dielectric and pn junction diodes. P-type doped regions (p−wells) isolate NMOS transistors, while n-typed doped regions (n−wells) isolate PMOS transistors. FIG. 2 illustrates the parasitic electrical elements, bipolar transistors, resistors and diodes, that co-exist within the CMOS structure. The source and drain regions of each MOSFET in the inverter form bipolar emitters. In normal operation, the circuit maintains a reverse bias of the diodes formed by the n−well/p−substrate, the p+/n− junction of the PMOS and the n+/p− junction of the NMOS. External factors such as leakage, circuit switching noise, particle upset, and transient overvoltage at the p+ diffusion or undervoltage at the n+ diffusion can trigger one of both of the parasitic bipolar devices into the active state. If either of the emitter or base junctions is forward biased, emitter currents will be sourced to corresponding base/collector regions, immediately shifting the local potential from its initial voltage state.

The network parasitic devices forms a pnpn silicon controlled rectifier (SCR) power device which can be unintentionally biased into a high current, low impedance state, thereby causing latch-up. The circuit elements R_{S1}, R_{S2}, and R_{S3} are the net effective bulk p− substrate resistors, while R_{NW1} is the n−well series resistance and R_{PW1} is the p−well series resistance. In conventional technology substrate resistors would have resistances on the order of 1 kΩ or greater. In a typical example of CMOS circuit operation, the bulk substrate represents ground potential (0 volts) and is referred to as V_{SS}. If current is injected from any source available to the p− substrate, the local potential (within the p− substrate) will increase in magnitude above zero volts as a function of the high value substrate resistance. The n+/p− diffusion diodes located in the p−well, and which were previously undisturbed, would then enter a forward biased conduction as the P− substrate potential increases above approximately 0.3 volts. It is this second contribution by the previously undisturbed n+/p− diffusion diodes which now positively enhances the initial small signal upset event, and can lead to latch-up. Likewise the same event is possible starting with forward biased p+/n− diffusion diodes which are located within the n−well isolation doping region that is caused by either an over voltage of the p+ diffusion or a transient under voltage condition existing within the n−well local potential, which typically equals the circuit supply voltage or terminal voltage (V_{DD}, or V_{CC}).

Thus, the network of series resistors plays a direct role in the transient bias states of the different impurity doped regions, which then directly influences the bias and conduction state of the diodes. Latch-up can be prevented by keeping the diodes in their reversed bias (off) states. A first step in reducing or preventing latch-up is reducing the effective resistance of p− substrate resistors R_{S1} and R_{S2}. The p− substrate resistance can be reduced using a high-dose buried layer (HDBL) 300 as illustrated in FIG. 3.

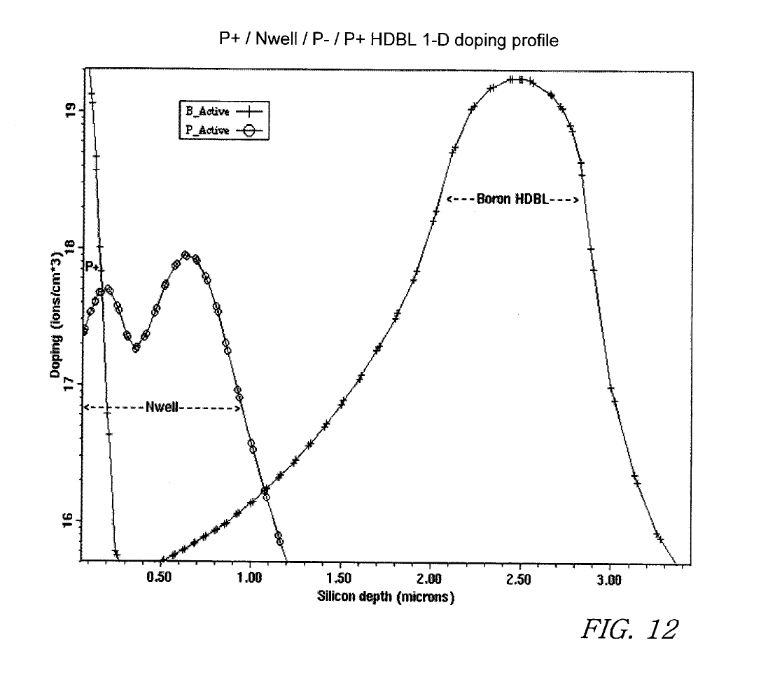

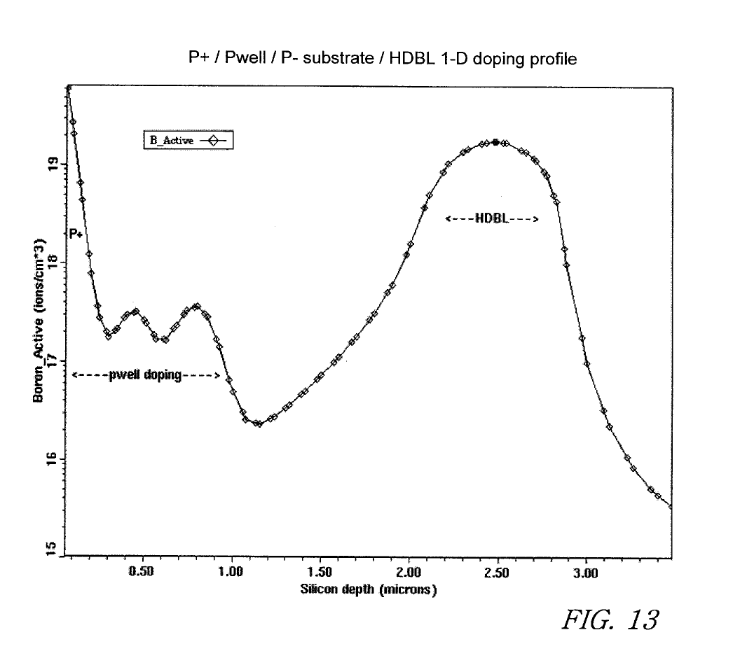

In the example of FIG. 3, HDBL layer 300 is a heavily doped region of the same conductivity type as the p− substrate, and is placed beneath the active device regions of the device by ion implantation. In general, both the doping and damage characteristics of HDBL influence device performance. HDBL structures are easily integrated into standard CMOS processing with the addition of typical steps such as, an implant step, a rapid thermal anneal (RTA), and an optional cleaning step in between the implant and anneal. The process steps associated with the HDBL can be performed either before or after dielectric isolation (SiO₂) formation either by LOCOS or the use of a shallow trench isolation (STI) structure common in many CMOS processes. While a variety of different impurities can be used, the most common implants are boron implanted at 1.0-2.5 MeV (for p-type substrates), and phosphorus at 1.5-3.5 MeV (for n-type substrates). If a wafer-normal to ion implant beam angle of zero degrees is set during ion implantation, the necessary energy to achieve a desired depth of the ion implant can be significantly reduced. Implanted doses typically vary between 1×10¹³ and 5×10¹⁵ cm⁻², which forms a highly doped and abrupt layer approximately 1.0-5.0 μm below the silicon surface. The buried layer peak doping concentration can range from 1×10¹⁷ cm³ to 5×10²¹ cm³. The buried layer is typically implanted sufficiently deep so that the final dopant profile (after all thermal processes) does not counterdope the retrograde well of opposite conductivity, which results in low well-substrate breakdown voltage. For example, a CMOS twin well process includes an HDBL structure (i.e., boron with an implant energy of 1.7 MeV and a dose of 1×10¹⁵ cm⁻² forming a blanket p+ buried layer). The 1-D doping profiles after all thermal processing steps are completed are shown for the p+/n−well region and the V_{SS} tie region in FIGS. 12 and 13, respectively.

For example, in the case of FIG. 3 where the substrate is p− doped, the deep p+ layer provides a low resistance shunt 300 that significantly reduces the series resistance between the pnp subcollector (below the n−well) and the p+ collector (V_{SS}). Forming a p+ shunting layer 300 via implantation also gives circuit designers the option of patterning the implant to independently optimize substrate resistivities in different areas, e.g., for a system-on-chip design. Thus, substrate resistors R_{S1} and R_{S2} are now significantly reduced, typically by more than two orders of magnitude, because of the presence of HDBL 300. The spreading resistance of the region can be lowered to less than 50Ω as compared to 2 kΩ or more for conventional CMOS isolation. However, use of the HDBL alone does not effect other parasitic resistances such as R_{S3} and R_{PW1}. Consequently, significant vertical resistance continues to exist.

A second step in addressing latch-up and other substrate current transients is to reduce the significant vertical resistance. Addition of a vertical conductor 310 extending between the buried layer 300 and a p−well contact region (as shown) or some other substrate surface terminal significantly reduces this resistance. In one embodiment, the vertical conductor 310 is formed as a vertical impurity region having the same conductivity type as the substrate, but typically having an impurity concentration greater than that of the substrate. For example, where the substrate is a p− substrate, vertical conductor 310 can be formed from one or more p+ implants into the region extending between p−well contact 320 and buried layer 300. High-energy ion-implantation combined with photoresist masking and/or multiple energy implantation can provide a vertical p+ doped region with high aspect ratio doping profile to bridge the uplink path from an ohmic V_{SS} surface contact or Schottky diode to buried layer 300 or other p+ bulk layers as is typical for p− epi on p+ bulk substrates. For example, in one implementation vertical conductor 310 is formed by multiple ion-implant steps at one or more energy levels.

When buried layer 300 and vertical conductor 310 are used in conjunction with each other, a new structure referred to as a buried guard ring (BGR) is formed. The BGR offers several isolation attributes. Since the low resistance deep buried layer is now locally connected via a vertical doping region or other conductor: (1) minimum impedance is provided for most or all of the accumulated, deposited or injected charge occurring within the silicon substrate region; (2) transient times for charge termination are reduced thereby improving overall isolation by reducing or minimizing the duration of any n+/p− diode forward biasing which reduces injected currents; (3) the BGR forms a low-resistance circuit leg back to the p−well contact terminal, thereby creating a current divider which effectively shunts and sinks a majority of any injected or deposited current away from the R_{S4} and R_{S5} resistor legs, thereby significantly reducing base current feedback to the parasitic npn devices shown and limiting voltage transients for the p-bulk silicon region associated with the CMOS structure. The BGR structure, by effectively shunting injected current or stray charge promptly to the V_{SS} terminal, reduces or prevents voltage transients which could subsequently forward bias either or both of the n−/p− diodes (n−well/p−substrate diode inherent in CMOS twin well isolation) and the n+/p− diodes (inherent in NMOS transistor) and eliminates subsequent triggering of the pnpn SCR network. Latch-up with the BGR isolation structure present then becomes difficult or impossible to initiate, thereby preserving the circuit from ever entering destructive latch-up.

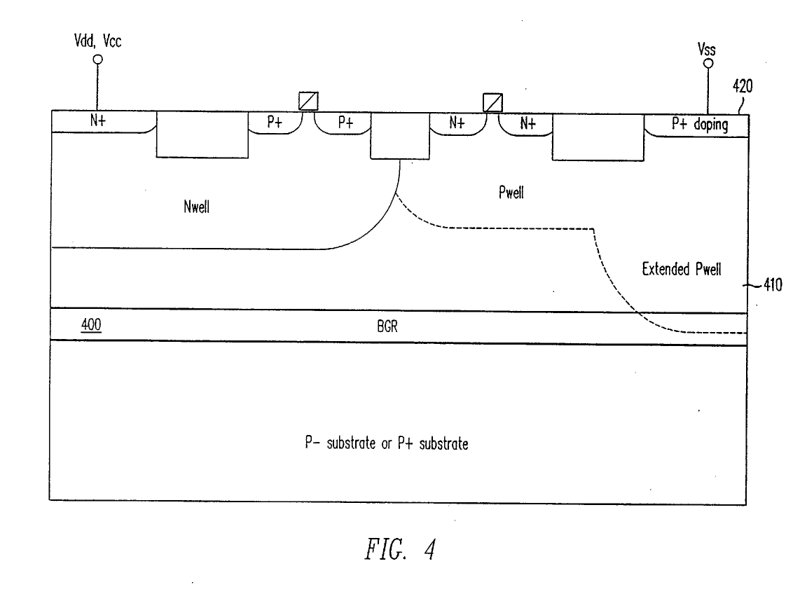

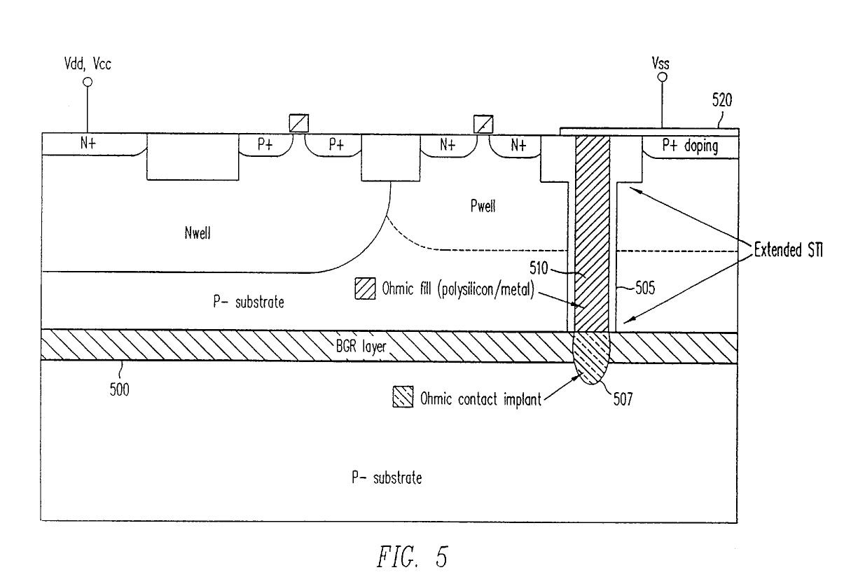

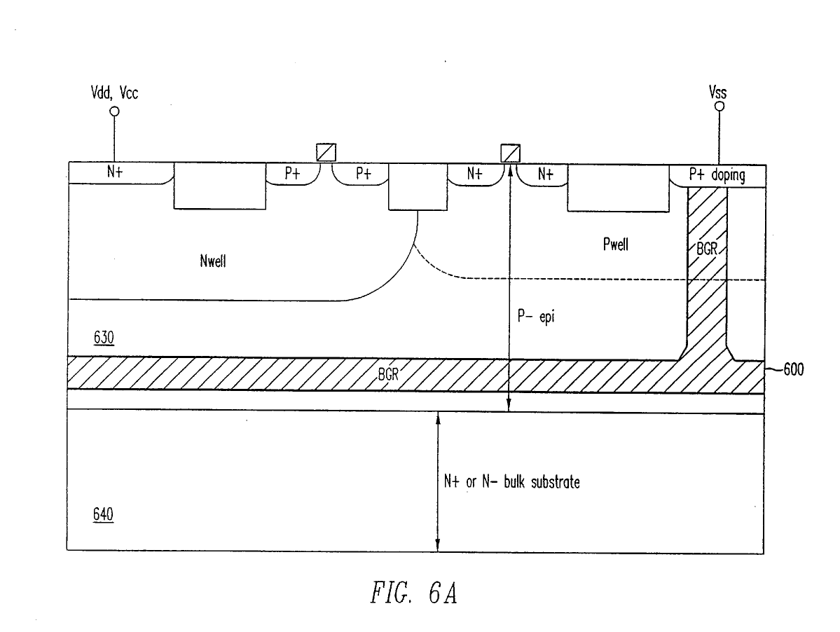

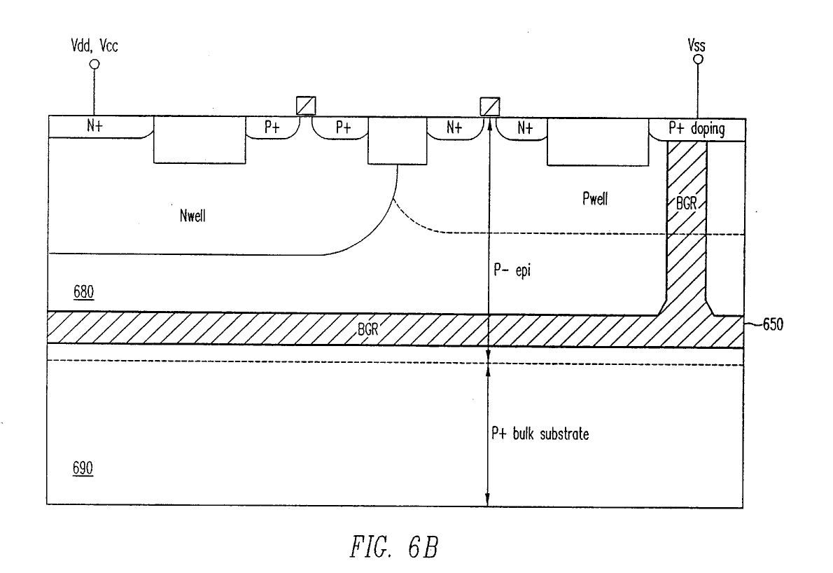

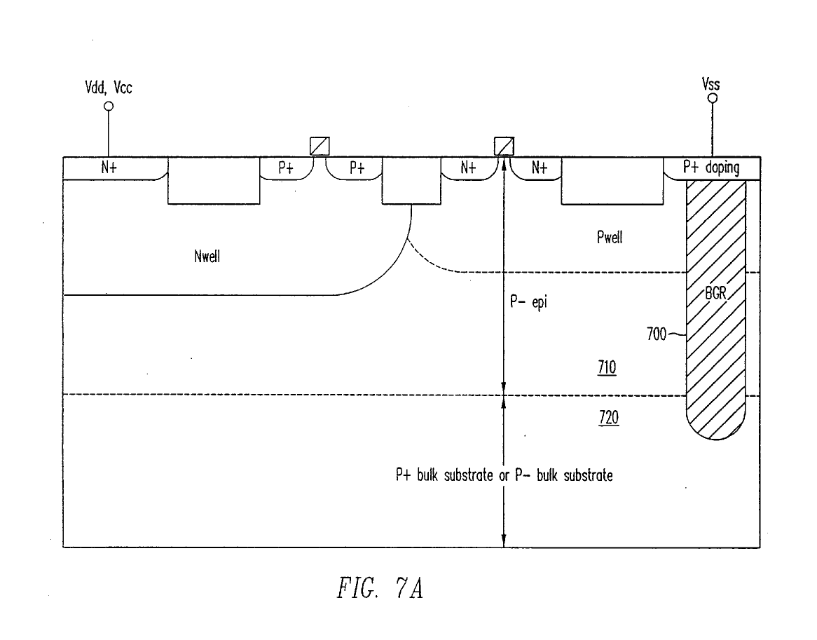

FIG. 4 illustrates and alternate implementation of the BGR structure. In this example, buried layer 400 is connected to p−well contact 420 using an extended p−well area 410 as the vertical conductor. Such an approach can potentially simplify device fabrication by making formation of the vertical conductor part of the normal p−well implant (or diffusion) process. Since the typical depth of buried layer 400 is from 1 to 5 μm, the p−well formation technique used should be capable of providing an adequately deep extended p−well. Moreover, extended p−well area 410 will typically extend well into buried layer 400 to ensure proper electrical contact.

In still other examples, the vertical conductor could be formed much the way vias or other vertical conductors are formed. For example, a deep trench that terminates at or near the top of a buried layer could be used. With appropriate spacer formation, silicide formation, and filling with polysilicon or metal, such a conductor could extend to the substrate surface where it would be capped in a conventional manner and terminated as appropriate in a metallization scheme. Conductor formation can also utilize emerging technologies, such as atomic layer deposition (ALD), or any other techniques as are well known by those having skill in the art.

FIG. 5 illustrates an example of direct connection using a metallization scheme to contact HDBL horizontal layer 500. In this example, shallow trench isolation (STI) structures are used to insulate the vertical conductor from the surrounding p−well and substrate. In a conventional STI structure, a shallow trench is etched into the substrate. The trench is then thermally oxidized and filled with a deposited oxide to make it non-conducting. Such a structure provides good isolation between adjacent MOS devices. However, in the example of FIG. 5, STI structure 505 is extended down to buried layer 500. Instead of filling the STI structure with an insulative material, STI structure 505 includes an ohmic fill (e.g., polysilicon and/or metal) to provide the needed vertical conductor 510. Electrical contact between vertical conductor 510 and buried layer 500 can be further enhanced using an ohmic contact implant 507. Ohmic contact implant 507 is typically an ion implant extension extending from the bottom of the STI trench well into the buried layer. P−well contact 520 is formed so as to be electrically coupled to vertical conductor 510.

FIGS. 6A-6B illustrate other implementations of the BGR structure. In FIG. 6A, BGR structure 600 (formed using any of the structures/techniques described above) and the CMOS inverter are formed in p− epitaxial layer 630 which in turn is formed on n+ or n− bulk substrate 640. As will be well known to those having ordinary skill in the art, various different techniques can be used to form epitaxial layer 630. Similarly, FIG. 6B illustrates a BGR structure 650 (again, formed using any of the structures/techniques described above) formed along with the CMOS inverter in p− epitaxial layer 680. Epitaxial layer 680 is in turn formed on p+ bulk substrate 690.

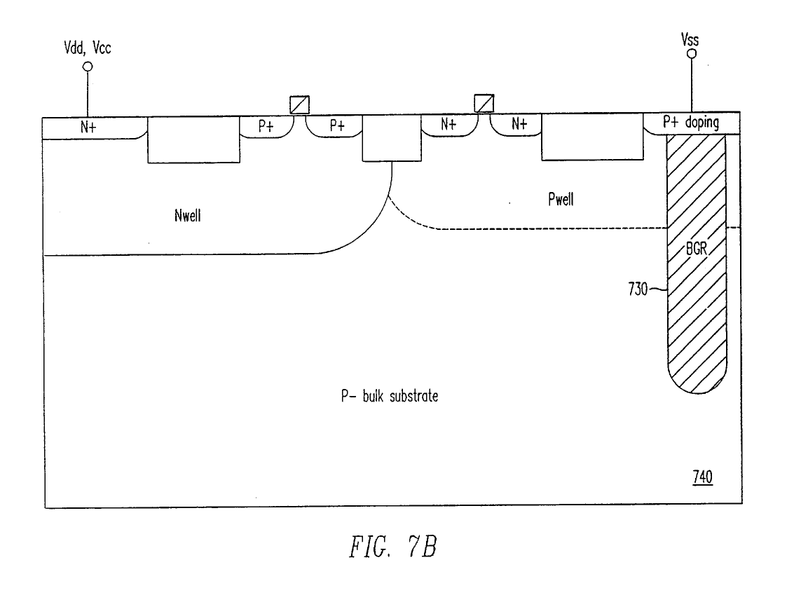

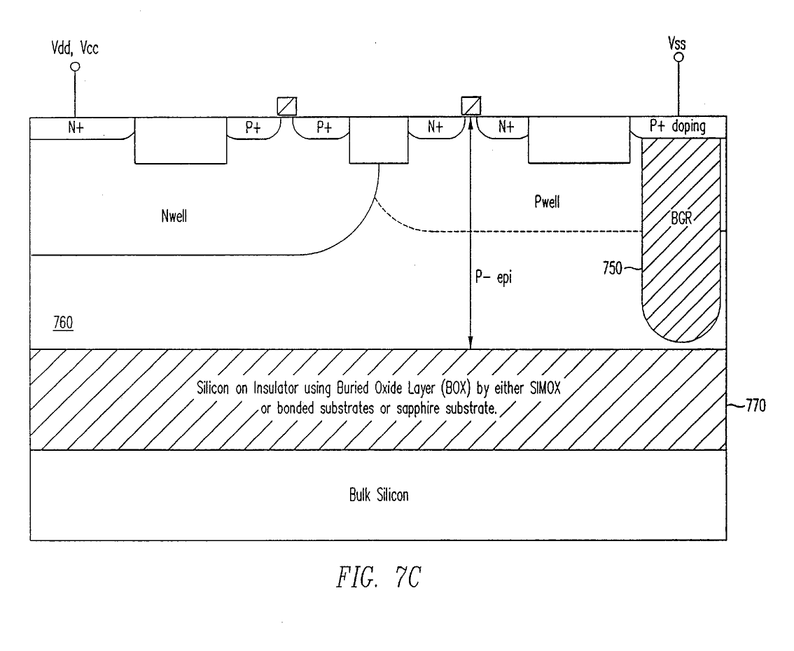

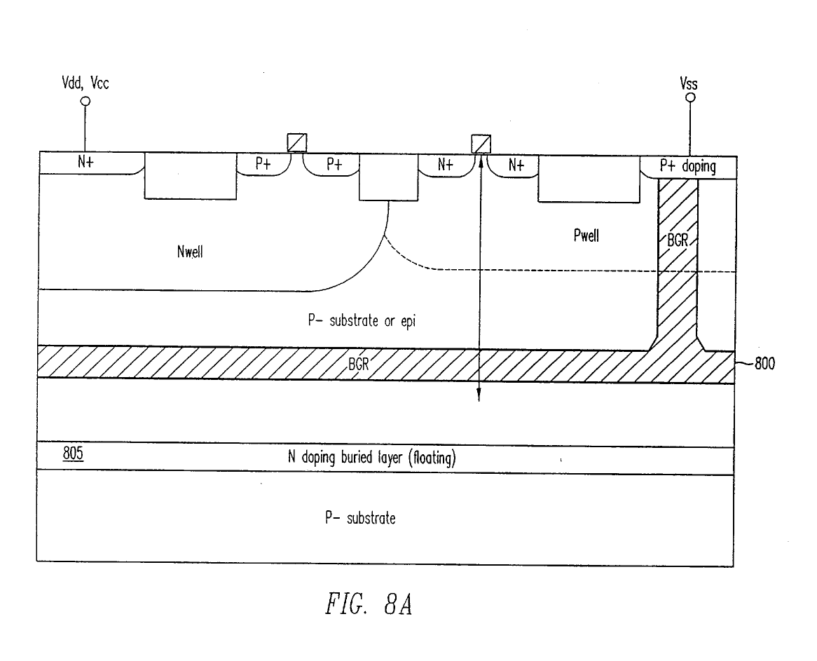

FIGS. 7A-7C illustrate still other embodiments and variations of the basic BGR structure. As shown in FIG. 7A, the BGR structure includes only a vertical conductor 700 (e.g., a vertical doping structure, deposited conductor, etc.), and does not include the HDBL described above. Such an implementation can provide adequate device benefits in some cases, particularly where the CMOS devices are very closely formed, such as in an SRAM implementation. In this example, BGR structure 700 extends to the p+ or p− bulk silicon substrate 720 while passing through p− epi layer 710, as would be used, for example, in a p− epi on p+ bulk wafer. Epitaxial layer 710 is in turn formed on substrate 720 and contacted using only the vertical BGR extension 700. FIG. 7B illustrates a similar implementation, where vertical BGR component 730 is implemented into p− bulk silicon. Similarly, FIG. 7C shows an implementation where vertical BGR component 750 is formed in an epi layer 760 which in turn has beneath it a buried oxide layer 770 (or other SOI implementation) formed using well known SOI techniques.

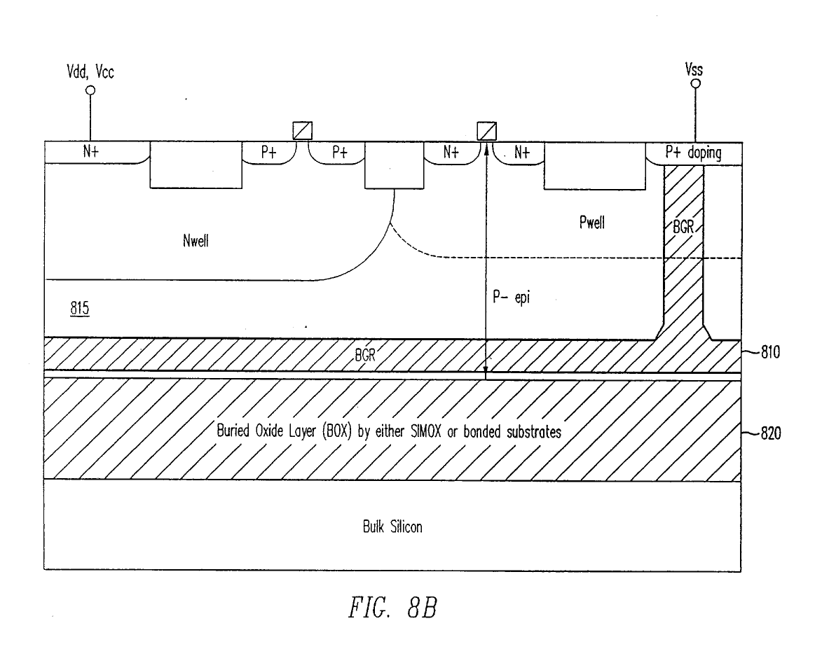

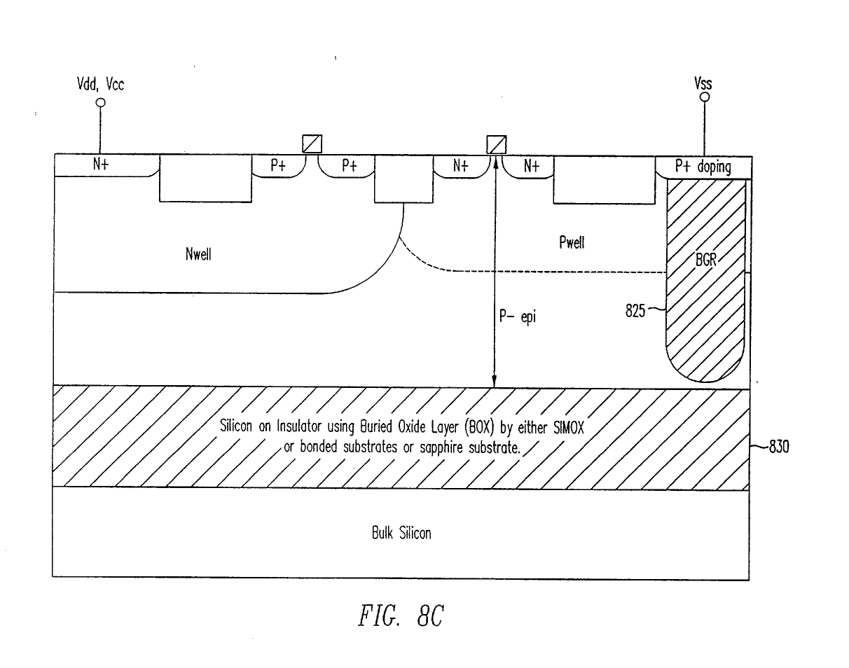

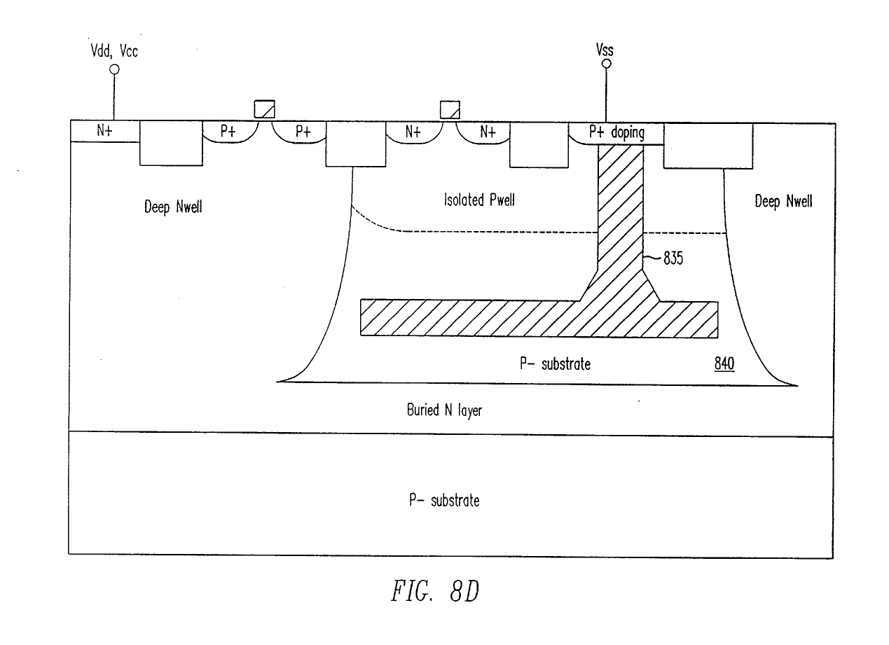

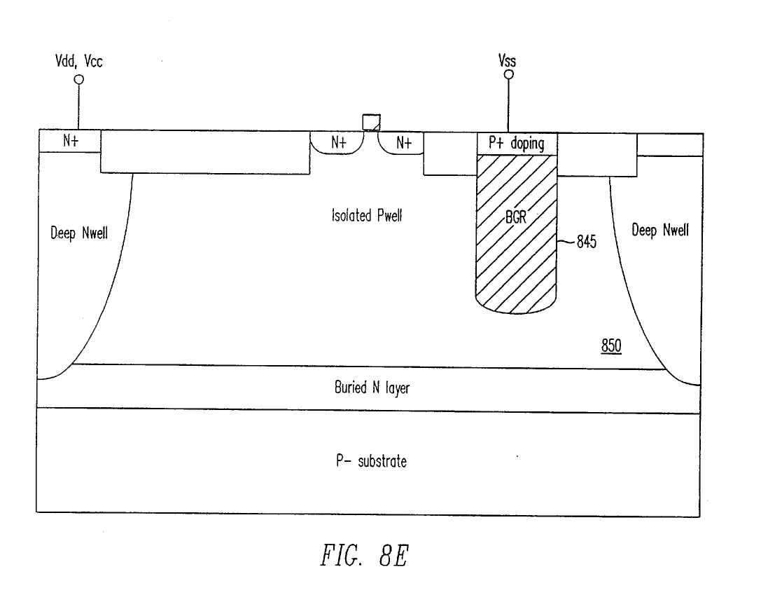

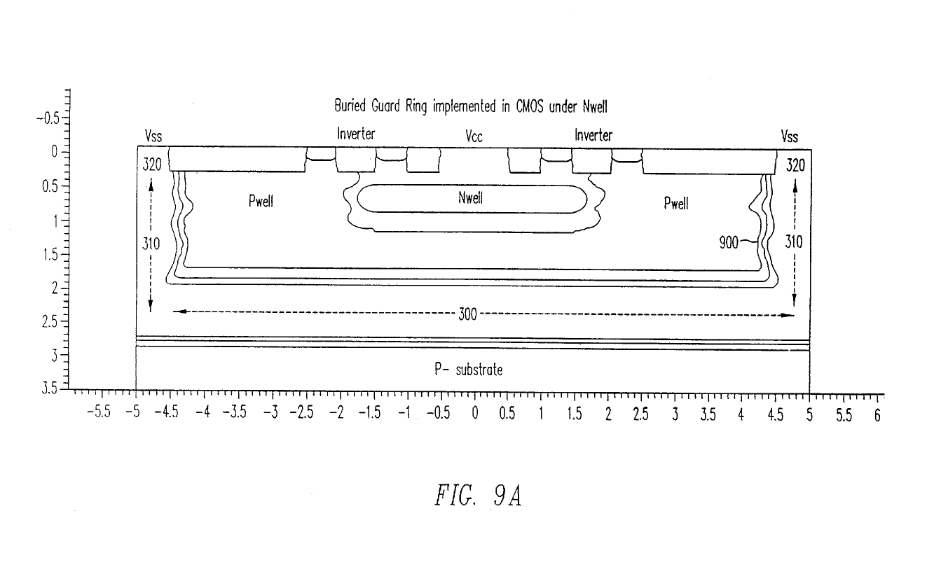

FIGS. 8A-8E illustrate still other embodiments and variations of the basic BGR structure. As shown in FIG. 8A, BGR structure 800 and a corresponding CMOS inverter have the same basic structure as that illustrated in FIG. 3. Note that in this example, as well as the examples of FIGS. 8B-8E, the BGR structure can in general be formed using any of the structures/techniques described above. However, an n-type doping layer 805 is included beneath the buried layer portion of BGR 800 to act as a carrier recombination and/or gettering layer. Layer 805 is typically left floating, i.e., it is not electrically coupled to ground or some other reference voltage. However, in other implementations, layer 805 can be coupled to a suitable potential. N-doped layer 805 can be formed using any number of implant or diffusion techniques, as will be well known to those having ordinary skill in the art.

As shown in FIG. 8B, devices using the BGR structure can implemented in silicon on insulator (SOI) substrates in order to take advantage of the unique properties of such substrates. In this example, BGR structure 810 and its associated CMOS devices are formed in epitaxial layer 815. Buried oxide layer 820 is formed in (e.g., using a separation by implantation of oxygen (SIMOX) process) or on (e.g., using a bonded wafer process) the bulk silicon wafer. Thus, BGR devices can further take advantage of the beneficial properties of SOI wafers including: reduced parasitic capacitance, additional SEU immunity, and in some cases simplified processing.

FIG. 8C illustrates an embodiment similar to that of FIG. 8B. However, in this case BGR structure 825 is formed from a single vertical conductive component as described above. BGR structure 825 typically extends through the epi layer to approximately the depth of buried oxide layer 830. In some embodiments, BGR structure 825 can stop well short of, or extend into buried oxide layer 830.

FIG. 8D illustrates still another example where the BGR structure is used with a CMOS device that includes triple well isolation, common for many RF devices. Here, BGR structure 835 is formed within the p− substrate region 840 of the isolated p−well common to triple well isolation implementations, but still surrounded (on the sides) by the deep n−well structures and (below) by a buried n-layer used to provide the additional isolation.

Finally, FIG. 8E illustrates still another BGR embodiment where BGR structure 845 is formed from a single vertical conducting structure and no HDBL. BGR structure 845 is implemented in the isolated p−well 850 of the triple well isolation structure. The final depth of the vertical BGR layer is consistent with the depth of the isolated p−well region and is typically less than 2 microns.

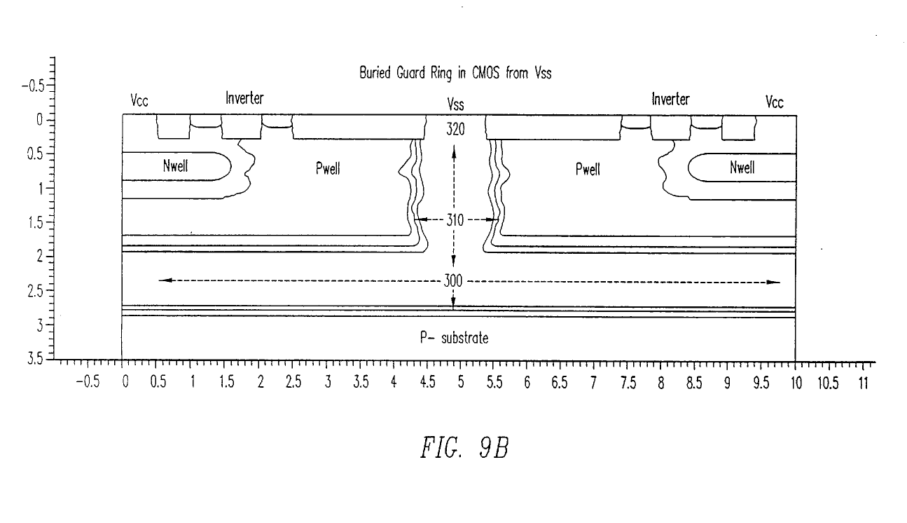

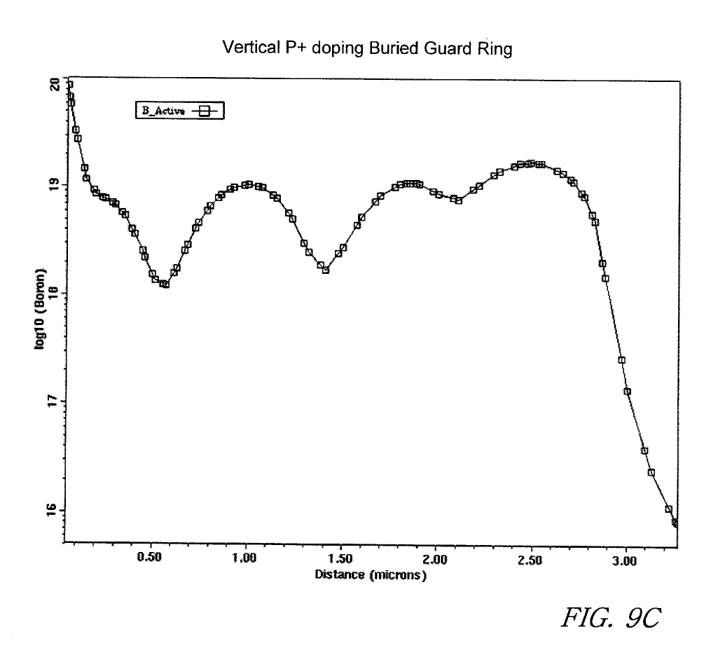

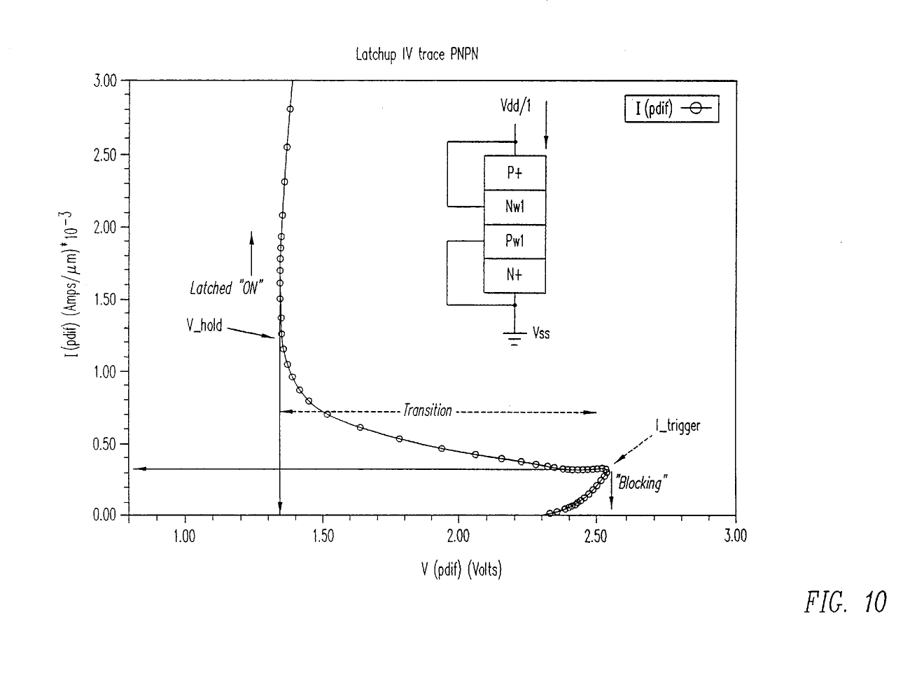

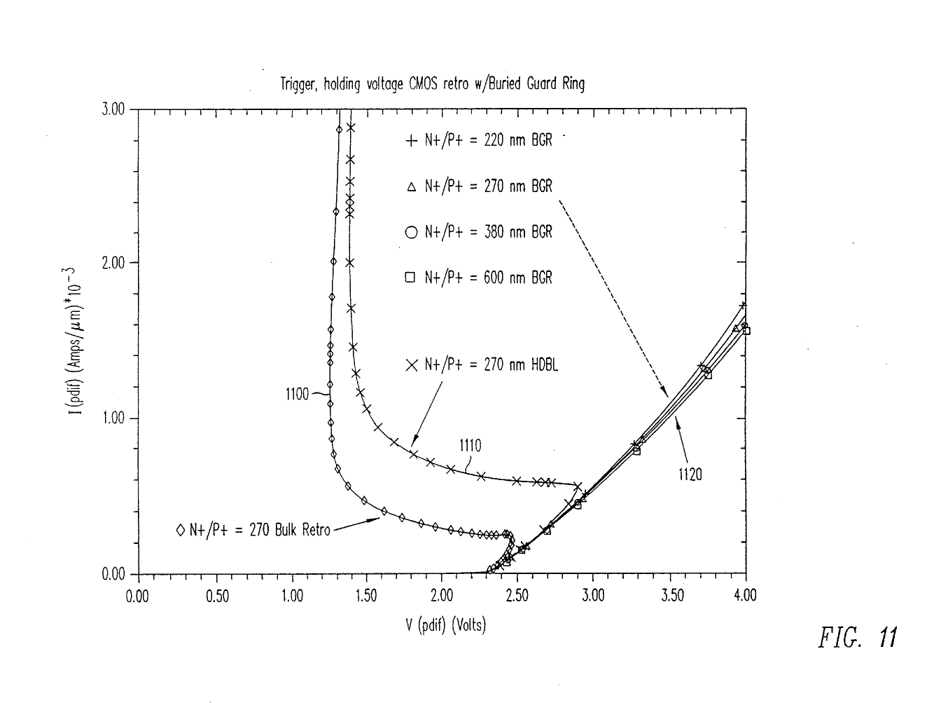

FIGS. 9A-9B illustrate a 2D simulation (using the Taurus-Medici device simulation tool from Synopsys, Inc.) of the doping profile of a CMOS twin well structure with the heavily p+ doped region now extending below the V_{SS} terminal to the p+ buried layer. FIG. 9A shows the BGR structure emphasizing its connection to the V_{SS} terminal, while FIG. 9B illustrates portions of the BGR structure under the device n−well. Contour 900 shows the 1×10¹⁸ cm⁻³ doping contour generally indicating the region of p+ doping that forms the BGR. Reference numbers 300, 310, and 320 show the buried layer, vertical conductor, and p−well contact 320 respectively. The impurity concentration of the BGR regions generally varies between 1×10¹⁸ and 1×10¹⁹ cm⁻³. FIG. 9C shows a one-dimensional doping profile from V_{SS} (i.e., below the p+ ohmic contact in the p−well) to the p+ buried layer. In general, the p+ vertical doping region is located only below the V_{SS} terminal (the p−well connection region) so that it does not interfere with normal circuit operations. As will be described below in connection with FIG. 11, the improved contact to the HDBL shunt layer is shown to be extremely effective in preventing latch-up triggering.

FIG. 10 provides a typical current vs. voltage (I-V) trace illustrating latch-up as well as terms and features normally used in conjunction with a latch-up I-V trace. In this example, the I-V characteristics of a p+ diffusion experiencing overvoltage are shown. The voltage at the p+ diffusion starts at V_{DD} (1.5 V) and is ramped to higher voltage as would be the failure mode of an overvoltage condition. Since the p+ diffusion is diode isolated from the n−well, it can only block current up to the forward bias diode built-in potential of approximately +0.3 V before becoming active. For overvoltages greater than 0.3 V higher than V_{DD}, (VBE) current is injected across the p+/n− emitter/base diode and collected in the base/collector junction. Once active, the pnp bipolar parasitic transistor actively injects current into the emitter base junction. The p+ emitter current is divided and flows to both the n−well base contact and the p+ collector (p−well). As the SCR trigger current is approached, pnp collector current is flowing to the V_{DD} terminal within the n−well, and significant hole current is flowing to the V_{SS} terminal which represents the pnp collector terminal. Note that prior to reaching the SCR trigger current, the n+/p− diode (which represents the emitter/base junction of the npn parasitic transistor) remains in the off state since, based on its local potential, it is still in a reversed biased blocking state.

If the overvoltage transient condition persists the vertical pnp (VPNP) will continue to inject holes into the p−substrate, which is terminated at the V_{SS} (ground) body tie. The VPNP collector current quickly drives the local potential in the p−well up from zero volts to +0.3 V above V_{SS}, which then forward biases the n+/p− diode since the n+ diffusion potential is fixed at V_{SS}. This n+/p− diode, which has been inactive so far, now begins to inject electrons into the p− substrate as the potential of the p−well continues to increase. The electrons (minority carriers) injected into the p−well will be collected at the CMOS n−well, since this is the highest available local potential node. The n−well is now acting as an npn sub-collector. The lateral npn (LNPN) collector current now provides significant current to the n−well base of the VPNP. LNPN collector current flows across n−well series resistors (FIG. 3). NPN collector current now flowing in the n−well forces an additional potential drop within the n−well (at the p+ diffusion) to some voltage below V_{DD}. The point on the I-V plot in FIG. 10 that marks the transition of the pnpn from the high impedance (blocking) state to the negative differential resistance state is called the trigger current. Trigger current is a meaningful term by which to judge latchup resistance capability since it is a measure of the current necessary to shift the “net potential” of the two independent diodes by +0.7 V. It is always desirable that the trigger current be as high as possible to prevent the pnpn from forward biasing to the low impedance non-blocking state.

A transitional phase or negative resistance occurs once the trigger point is passed and the pnpn network transitions from the low current blocking state to the high current, low impedance state. Finally, the I-V curve reaches its minimum voltage value (vertical portion of FIG. 10). Just after the trigger point is passed, the current flowing between the two voltage rails (V_{DD} and V_{SS}) moves from the substrate and n−well resistor to the surface, where the resistance is lowest. Even though the sheet resistances of the n−well and p−well regions along the edges of the STI are high, the spatial separation between the p+ diffusion (V_{DD}) and the n+ diffusions (V_{SS}) is small. The current flowing between V_{DD} and V_{SS} has now reached the lowest network resistance, and the associated voltage drop also reaches its minimum value. The aforementioned shunt resistors determine how much current is retained in the network resistor legs, and any current remaining here is subtracted from the base currents of the VPNP and LNPN, decoupling the bipolar effectiveness. Latch-up that reaches this saturation stage will cause overheating and can melt both the silicon and metal regions from the heat generated by the large currents being passed. The holding voltage is the minimum voltage for which positive current feedback can be sustained by the VPNP and LNPN pair.

With this in mind, FIG. 11 illustrates the significant improvements made possible when BGR techniques are applied to a conventional CMOS isolation scheme. Several curves are illustrated. The lower curve 1100 is a typical latch up I-V trace for an advanced CMOS technology with advanced n+/p+ spacing of 270 nm. The I-V trace shows that snap-back (latch-up failure) has occurred at approximately 200 μA/μm, and the latch up holding voltage is approximately 1.2 V. The second curve 110 shows marked improvement associated with the presence of an HDBL, with snap-back now >500 μA/μm and holding voltage approximately 1.4 V. However in both cases latch up has occurred with a holding voltage that is below the power supply of 1.5 V. The remaining curves 1120 which represent IV characterization in the presence of a BGR structure show that no triggering event has occurred for even smaller n+/p+ spacing of 220 nm and with over voltage currents >1.6 mA/μA/μm. The lack of latch-up snap-back at these currents marks an improvement of more than 3 orders of magnitude. The simulation data shows the effectiveness of the BGR structure in preventing latch-up, even at extremely aggressive 220 nm n+/p+ spacing.

The three dimensional heavily doped BGR layers extend both horizontally and vertically thus creating low ohmic regions of contiguous and/or connected to isolation doping regions which stand separated from the transistor doping regions. As can be seen in FIGS. 3 and 9A-9B, the BGR structure can be integrated into any existing CMOS twin well isolation structure with no adverse impact to existing structures, thus enabling the improvements necessary to provide robust isolation for both conventional circuit noise initiated latch up and single event latch up. Moreover, BGR structures and techniques can be used to prevent latch-up in both radiation-hardened and conventional microelectronic circuits. BGR structures and techniques can also be implemented on a variety of different process variations, such as epitaxial silicon on bulk silicon (either with or without a heavily doped substrate), SOI, SOS, and the like.

The BGR structures and techniques can also be used to reduce or eliminate both single-event upset (SEU) and single-event transient (SET) events. SEU and SET can be caused by a high-energy particle, e.g., a single heavy ion or nuclear particle such as a neutron or alpha particle, passing through a critical node in an IC. Immediately after being struck by such a particle electrons and holes will be separated from the silicon lattice as a function of the particle's energy which is expressed as the linear energy transfer (LET Mev/mg-cm) of the particular particle. If the charge deposited and ultimately collected as free electrons and holes is greater than the critical charge of a memory cell or some other state-related device, a single-event upset can occur. The susceptibility of ICs to single-event upsets typically depends on the amount of critical charge required to “flip” a bit and the probability that a particle with a LET large enough to deposit that critical charge will strike a sensitive node. The production of large numbers of electron/hole charges also creates a potential dipole within the particle track passing through the silicon material. The Hall effect segregates the holes and electron charges to opposite sides of the electrostatic field. Some electrons and holes can recombine in the lattice via SRH and Auger mechanisms. However, as a result of their higher mobility, electrons are quickly collected at the positive terminals, whereas the net concentration of holes, which have lower mobility and remain with the silicon body as static charge while unrecombined because of depleted electrons. The positive charges cause the local potential of the p-substrate to increase in voltage to a positive value and continues to influence the local potential of the p− substrate positively for several nano-seconds after the high energy particle strike. As a result of the potential upset within the p− substrate, other unstruck diodes are now activated which creates secondary currents and enhances the initial upset more significantly, an effect often referred to as single event transient (SET). While soft error results in data corruption, it is not destructive to the physical circuit.

Since CMOS logic typically uses inverter gates and cross coupled logic gates to store binary bits in any digital circuit, the aforementioned BGR devices and techniques will prove useful in reducing SEU and SET. The BGR structure serves a similar role with regards to soft error as in the latch-up isolation. In both cases the BGR structure effectively sinks excess positive charge generated by the upset event, while maintaining node potential, and limiting the transient voltage swing and duration following an SEU, SEL, or SET event. Process and device simulations are used to quantify the effectiveness of the BGR structure using what is known as mixed-mode simulation. Test cases for SEU upset have been simulated for heavy ions (krypton) with LET of 110 Mev/mg-cm. In these simulations, where an inverter is brought to either a digital “one” state or a digital “zero” state and the mixed-mode SEU simulation is executed. In 21 different cases (21 different ion strike points, or angles of strike), the conventional CMOS inverter was shown to fail, i.e., an SEU occurred 9 times out of 21, or 43% of the time. In the simulations, the SEU charge transfer is completed within by 50 ps of the event, however the simulation was continued to 1 ns to observe charge recovery and circuit response.

Results from the same simulations using a CMOS inverter with a similar structure but now including the aforementioned BGR structure show marked improvement. In this example, there are no failures in the same 21 cases. While the BGR structure demonstrated no failure in 21 SEU tests, the contrast with the bulk silicon simulations is even more significant. In several cases of the BGR structure simulations, significant improvement both in voltage stability and transient response were seen. The BGR structures, when compared to the bulk example, appear to “clamp” the node potential for certain SEU strikes and completely eliminates the possibility of secondary injection by the unstruck nodes since the p− substrate potential is maintained at or very near zero during SEU events. Moreover, simulation studies indicate that the BGR structure would significantly improve SEU and SET soft error when compared to conventional CMOS without BGR protection. The simulation studies also indicate that BGR effectiveness in reducing SEU events depends at least in part on the net resistance of the structure. For example, reducing the resistance of the HDBL in the BGR improved performance of the structure. Such resistance reduction can be optimized, for example, by using shallower HDBL implants, by increasing the implant dose, and/or by optimizing the vertical doping profile.

### Backside BGR

Many devices described above incorporate a BGR structure in which a vertical conductor (e.g., a vertical implant region, metallization, or the like) generally connects a high-dose buried layer HDBL portion of the device to a surface terminal of the die (e.g., a p−well contact region), which can be coupled to ground. By so doing, the HDBL portion and the vertical conductor structure together form the BGR structure. When so connected, the HDBL portion may be viewed as a horizontal buried guard ring (HBGR) layer (e.g., see labeling of HDBL layer 400 as a BGR layer in FIG. 4, and elsewhere) and the vertical conductor structure may be viewed as a vertical BGR structure (VBGR).

Rather than contact the HBGR layer through a set of implants (or other conductive pathway) to the top surface as described above, the HBGR layer can be operably contacted to ground (or to another suitable “well” voltage) through the backside of the wafer or circuit die, thus forming a backside BGR (BBGR) structure. In certain embodiments, the starting wafer may be highly doped to reduce the resistance from the HBGR layer to the back of the wafer, which is then further contacted to the package for eventual connection to ground. The reduced resistance can be accomplished, for example, using an epitaxial P− layer (i.e., lightly-doped P−type layer) grown on a P+ layer with enough thickness to accommodate the NFET and PFET devices of the circuit without interference from the initial P+ bulk wafer doping. Various alternative techniques can be used to conductively couple the HBGR to the backside of the die including, for example, vertical implant regions between the HBGR and the backside of the die.

Other BBGR configurations are also useful. In certain embodiments the starting wafer substrate can be of a low doping density (1e14 to 1e17 ions/cm³) and to which a high energy boron implant (ranging from approximately 1.0 MeV to 1.7 MeV) is performed using a dose that can range from 5e13 to 5e15 ions/cm² to form the HBGR layer, and which layer is contacted to ground at the back of the wafer or circuit substrate die.

In certain BBGR embodiments the heavily doped boron horizontal layer (i.e., the HBGR layer) is implanted as a blanket layer (i.e., no photomasking, and thus implanted everywhere) and vertically positioned at a depth sufficiently below the Nwell to avoid significant counter doping of the Nwell. In certain embodiments utilizing a low-doped substrate wafer, an epi layer (i.e., epitaxial layer) need not be grown, in which case the HBGR implant may be performed at a high energy (e.g., approximately 1-2 MeV).

The performance of such devices is further improved through the use of an electrically conductive adhesive between the backside of the die and certain portions of the package to electrically connect the silicon region to the package's conductive header or substrate, which in turn is typically connected to one or more package pins/balls. In some embodiments, the backside of the die can undergo preparation steps before application of the adhesive, such as lapping, deglazing, die thinning, backside surface metallization, etc. Various different electrically conductive adhesives can be used including metallic pastes, conductive epoxies, conductive thermoplastics, and cyanate esters. Moreover, these techniques can be used with various different types of packages.

One preferred embodiment of a BBGR structure uses a highly doped P+ starting wafer (e.g., boron 1e19 ion/cm³) on which a lightly doped P-type silicon epi-layer is grown. The heavily-doped bulk substrate is used to reduce the vertical resistance from the HBGR layer to the back of the wafer, which is then further contacted to ground (or to another suitable “well” voltage) through the package. The epitaxial p− layer is grown on the P+ bulk silicon wafer with enough thickness to accommodate the NFET and PFET device construction without interference from the (deeper and heavily boron-doped) starting wafer.

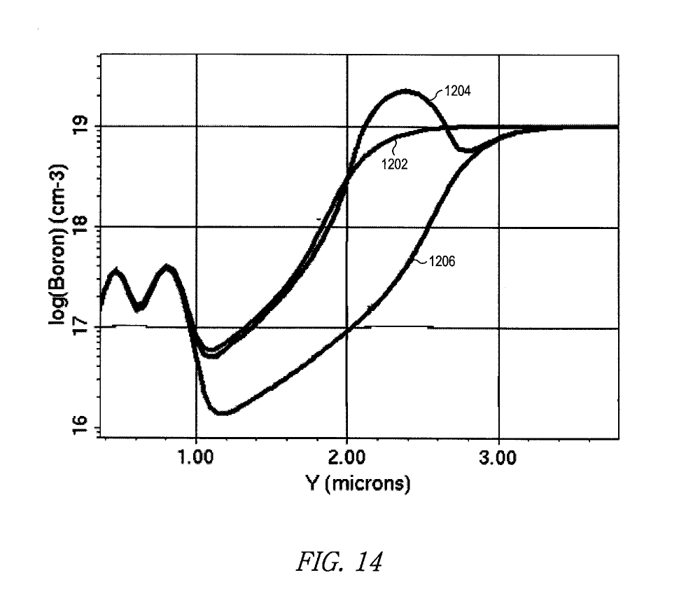

After the epi-growth, a high energy Boron implant is performed at an energy ranging from approximately 1 MeV to 2 MeV and with dose ranging from 5e13 to 5e15 ion/cm² to form a horizontal boron doped layer, which is deep enough to avoid significant counter-doping of the N−well and is preferably at least partially overlapped with the substrate doping. The boron doping profiles for this case, with a HBGR implant (curve 1204) and without the HBGR implant (curve 1206), are plotted in FIG. 14 vs. depth into the wafer. The third boron profile, indicated by curve 1202, corresponds to a case without the HBGR layer implant and also formed on a thinner epi layer, is also shown to compare its slope to that of the case with the HBGR implant. During the epitaxial growth step, the boron doping from the high boron doped starting wafer out-diffuses upward into the epi layer, and creates the long and rather gradual tail as shown here (1206) which can cause interference with shallow doping regions. This effect imposes a limit on how close one can position the heavily doped region to the surface regions where the transistors are formed. Using a MeV implant technique, a more desirable abrupt transition (positioned closer to surface with greater than 3× higher peak concentration) between the lower doping regions necessary in the transistor surface region, and the more heavily doped region of the wafer is desired. This technique also allows for formation of “higher” peak doping concentration in the layer (1204) since the doping of the MeV implant is added to the existing doping of the heavily doped bulk wafer. This effect has advantages in that even higher concentrations can be achieved while not interfering with shallow doped regions than is possible with convention techniques.

The formation of a close and heavily doped layer is very desirable for suppression of minority carrier (electrons in P-type) life time and shunting of majority carriers (hole charge in P-type) to contacts (e.g., a grounded terminal). The combined effect of the more heavily doped and closer, more abrupt boron layer is both reduced ohmic resistance for the hole carriers and a higher recombination rate for excess electrons. Because the HBGR layer is a high energy ion implant layer, it can be added at any point in the process which can be used to avoid hotter and longer thermal diffusion steps typically used early in the silicon process, thus preserving a more highly abrupt doping profile over a wider range of doping concentrations than is possible with the out-diffused boron from the initial wafer. This feature also allows the doping layer to be located much closer to the active transistor device region and with a higher peak concentration, without interfering with the doping profiles of the transistors.

An example of the advantage of “peak doping location” can be seen by comparing the doping profile 1206 (in FIG. 14) to the doping profile 1204 (with MeV implant added) at approx Y=2.3 microns. The MeV implant added to the existing doping has resulted in a significantly increased peak doping concentration that is approximately 17× higher than profile 1206 at the same Y depth. Additionally, the boron doping peak concentration, which is equal or greater than 1e19 ions/cm³, is now positioned more than 1 micron closer to the surface (shown by profile 1204, where Y=2.1 microns) as compared to the conventional profile 1206, which drops below a peak concentration of 1e19 at Y=3.2 microns, and without interfering with shallow doped transistor regions.

The MeV implant (used to form the HBGR layer), combined with prior doping represented by profile 1206, now forms a new “net” doping profile 1204. As can be seen in the figure, comparing the doping concentrations of the two profiles 1204, 1206 at a depth of approximately 2.3 microns, the doping peak of profile 1204 (MeV implant+heavily doped bulk) shows a peak doping concentration of greater than 2e19 ions/cm³ compared to the conventional doping profile 1206, which shows a doping of approximately 5e17 ions/cm³, which is in excess of 17× lower than profile 1204 at this depth. Because of this, a significant advantage is realized by profile 1204 in that the shallower and more heavily “peaked” the doping layer is formed, will act to reduce series resistance and also the sensitive volume with respect to single event effects, without interfering with normal device operation. Such techniques can achieve a resistance between the HBGR layer and the backside of the wafer that is less than 1000 ohms.

Another advantage of the HBGR layer (profile 1204) is that the higher peak concentration of Boron, greater than 1e19 ions/cm³ and positioned much closer to the surface acts to suppress single event effects in the following ways. During a single event strike by a radiation particle (atomic or nuclear) the two component free carriers generated (frenkel pair=electrons and holes) are affected completely differently by the presence of the heavily doped boron layer. The positive charge is now more readily collected in the HBGR layer and benefiting from increased boron doping (lower Resistance), the charge will quickly spread out laterally which then acts to reduce the positive charge density and electric field before the positive transient current to the backside wafer contact is terminated. In effect the HBGR layer is acting as a solid state micro-lighting rod to both suppress electrons by recombination, and sink positive charge by reducing the p-substrate electrical resistance. The additional doping in the HBGR layer (added by MeV ion implant technique) near the surface reduces substrate resistance much more than if that same implant dose were added to the wafer earlier in the process, because an earlier implant would expose the doping to more diffusion, which would then spread the doping more uniformly throughout the wafer, reducing the peak concentration and increasing the substrate resistance.

This BBGR approach offers several potential advantages over a “top-side” contacted BGR structure (i.e., having a vertical connection ultimately to the top surface the die). First, a BBGR process is advantageous for process and design portability. The BBGR requires only a different starting wafer and a blanket implant for the HBGR layer relative to a standard bulk process. Circuit layouts originally designed for a standard (lightly-doped) bulk silicon wafer process, and which are sensitive to radiation, would be improved using the BBGR without any design or layout changes. This results in radiation hardening the circuit to single event effects.

Second, the BBGR may afford a more compact layout. The use of BBGR requires no change to the P−well contact regions and the HBGR layer is contacted without the need for additional top-side P−well vertical contacts. These contacts and contact diffusions may also be removed, optionally, to reduce space. Third, the BBGR has an advantage in providing for reduced impedance. The BBGR would have both less resistance and less inductance to ground than the top-side contacted BGR. In turn, this will make it that much more difficult for a high-LET (“Linear Energy Transfer”) strike to forward-bias any of the parasitic bipolar junctions.

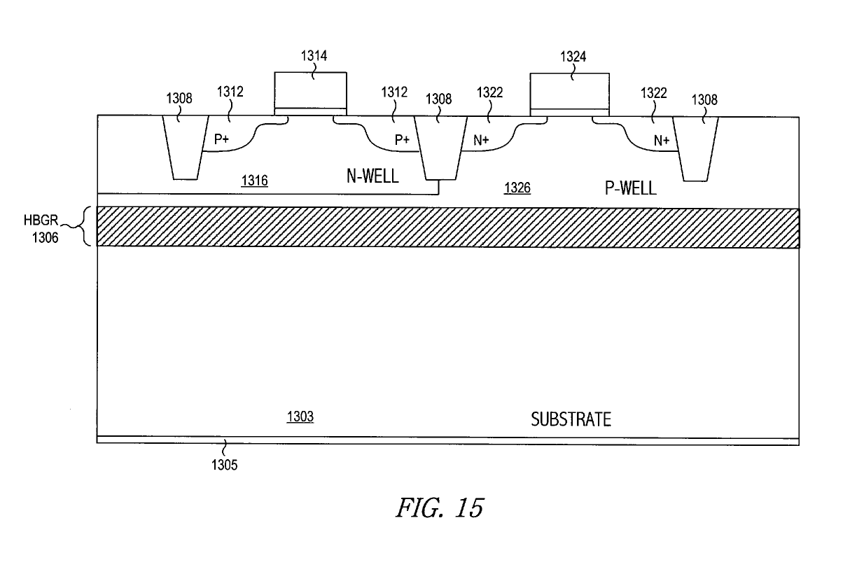

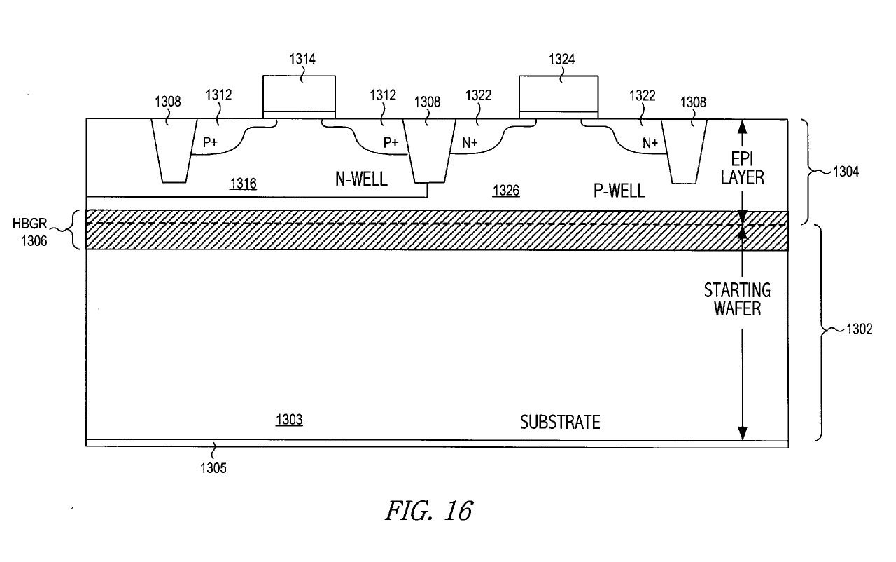

There are variety of BBGR embodiments that are contemplated. One such example includes forming a HBGR layer in a bulk P-type wafer, and making contact from the backside of the die (once each die is “singularized” from the wafer) to the package within which the die is assembled. A semiconductor process corresponding to such a case is depicted in FIG. 15. A pair of transistors is shown fabricated upon a substrate 1303. Substrate doping for the starting wafer can range from a lightly doped boron concentration (e.g. less than 1e15 ions/cm³) to a much higher concentration of greater than 1e19 ions/cm³. A PMOS transistor includes source/drain regions 1312 and a polysilicon gate 1314, and is formed within an N−well region 1316. An NMOS transistor includes source/drain regions 1322 and a polysilicon gate 1324, and is formed within a P−well region 1326. Trenches 1308 are used to separate the N−well from the P−well. A horizontal BGR layer 1306 is formed below both devices, and may extend beneath some or all such devices, as described herein. The backside of the wafer 1303 may include a metallization 1305 to facilitate a low impedance connection with a header of die-attach pad within a semiconductor package for the die. Such a metallization 1305 may be particularly useful for eutectic bonding of the die to a package, but may also be useful if the die is epoxy (or other electrically conductive adhesive) bonded to a package.

Rather than a bulk wafer, an epi-layer may be formed on a heavily-doped P-type wafer. In certain embodiments, the HBGR layer may lie along the intersection of the epi-layer and the starting wafer, which is depicted in FIG. 16. A starting wafer 1302 is preferably a heavily-doped P-type wafer, upon which a lightly-doped P-type epitaxial layer 1304 is grown. The HBGR layer is formed (e.g., as by ion implantation through the epi-layer 1304 as described above) to straddle the interface between the starting wafer 1302 and the epi-layer 1304. An exemplary embodiment may have the doping profile 1204 shown in FIG. 14. The NMOS and PMOS transistors are shown as before, and the horizontal BGR layer 1306 may be formed below both devices as shown, and may extend beneath some or all such devices, as described herein. As before, the backside of the wafer (i.e., backside of substrate 1303) may include the metallization 1305.

The p-type HBGR layer need not be formed beneath the entire circuit, nor even beneath both NMOS and PMOS transistors. In other embodiments, the HBGR layer may be patterned to provide for such a layer beneath the NMOS transistors (i.e., beneath the P−well region), but to prevent the HBGR layer from being formed beneath the PMOS transistors (i.e., beneath the N−well regions).

The backside contact of the wafer (i.e., “die”) for certain embodiments described herein may be accomplished using a conductive epoxy, and need not require a metallized back surface of the wafer. Such epoxies are well known in the art. In addition, the backside contact to a singularized die may also be accomplished using a solder, such as a gold eutectic solder, in which case a metallized back side may provide a lower overall resistance to the pad or header to which the die is attached, and thus a lower overall resistance to the ground afforded by the package pin connected to the header or pad. A thin layer of gold may be advantageously evaporated onto the back of the wafer for such backside metallization. To decrease the effective resistance of the backside contact, the starting wafer may be “thinned” before individual dies are separated, and also before any backside metallization is applied.

### Deep and Shallow HBGRI Deep and Shallow Trench

FIG. 16 illustrates two useful concepts. The first concept is the combination of shallow trenches 1308 and deep trenches 1404 in a process where the deep trenches 1404 are used primarily at the N−well/P−well boundaries. Although depicted in this figure as such, the N−well junction (i.e., the depth of the N−well) is not necessarily deeper than the deep trench.

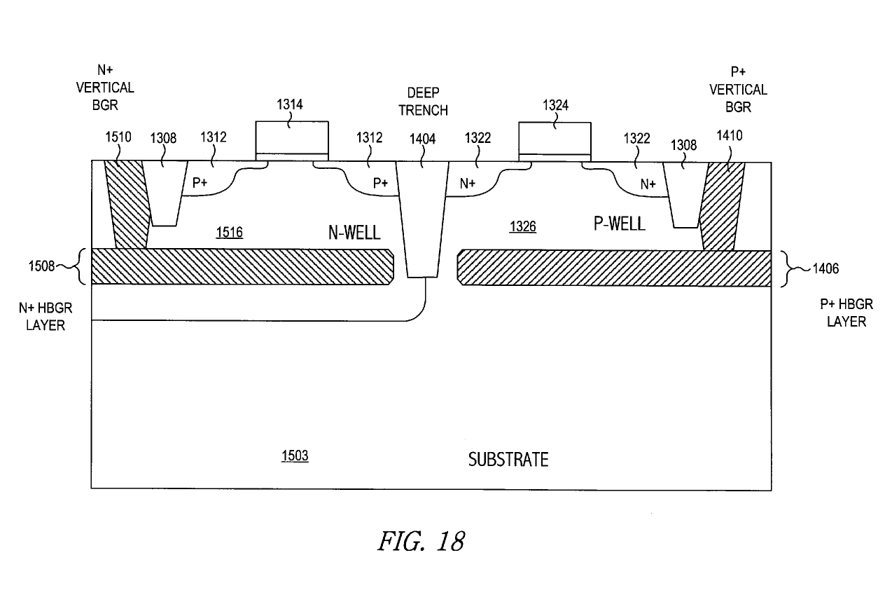

The second is the combination of a shallow HBGR layer (e.g., layer 1406) and a deep HBGR layer (e.g., layer 1408). In the embodiment shown, the deep buried guard ring layer (Deep HBGR layer) 1408 is used to provide some protection for the N−well 1416 and the devices within the N−well 1416. An exemplary Deep HBGR layer 1408 may be formed by implantation with an ion implant energy of 1.0 to 2.0 MeV and an implant dose from 5e13 to 5e15 ions/cm². If the Deep HBGR layer 1408 were placed too close to the N−well (i.e., measured in the direction normal to the surface of the wafer), it would counter-dope the N−well somewhat, which would increase the Beta of the parasitic PNP device having the N−well as its base. In the P−well under the NFET's, however, it is desired to form a more shallow buried guard ring layer (Shallow HBGR layer) 1406 to be as close to the surface as possible without affecting device performance. The Shallow HBGR layer 1406 is masked with photoresist to provide for selectively forming the Shallow HBGR layer within certain P-type regions. For an exemplary process, the Shallow HBGR layer 1406 may be implanted at an energy from 300 KeV to 1.0 MeV and implant dose from 3e13 to 5e15 ions/cm². The Shallow HBGR layer 1406 may be top-side contacted using a vertical BGR region 1410, as described above. While the shallow HBGR layer 1406 is depicted as a heavily-doped P-type structure, in other embodiments an analogous heavily-doped N-type shallow HBGR layer may be provided, such as that shown in FIG. 18. Therefore, since there are differing criteria for buried layers within N−well and P−well regions, it is useful to provide two different conductivity types of shallow HBGR layers. In either case, the Shallow HBGR layer is combined with a VBGR to form a shallow BGR. In the embodiment shown, the Deep Horizontal Buried Guard Ring layer 1408 is not patterned, and is electrically connected only through the back side of the wafer (or integrated circuit die, if separated into individual dies).

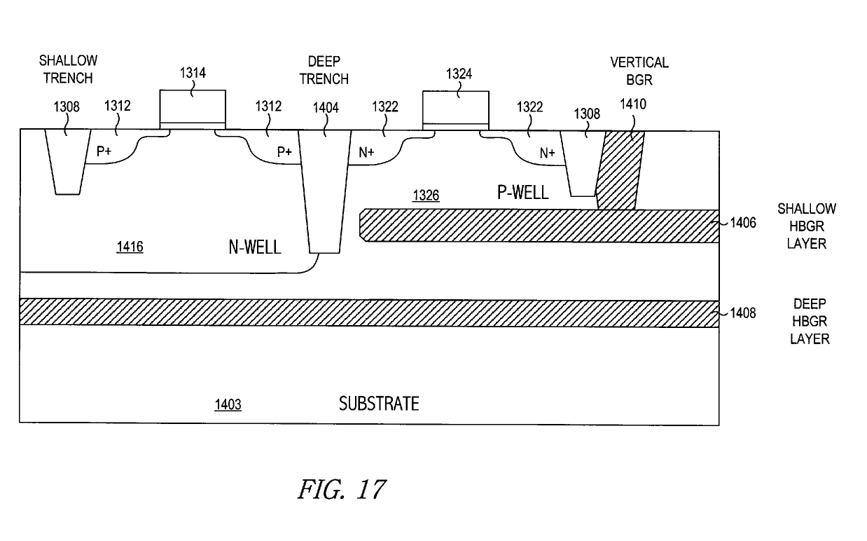

There are numerous additional embodiments that are contemplated. For example, if the structure shown in FIG. 17 may be fabricated using a P+ substrate with a P− epi layer formed thereupon. The interface between the P+ substrate and the epi layer may fall within the Deep HBGR layer 1408 such that the Deep HBGR layer 1408 straddles the P+/P− interface. Alternatively, the P+/P− interface may fall below (i.e., deeper than) the Deep HBGR layer 1408. In certain embodiments a heavily-doped P+ substrate itself may take the place of the Deep HBGR layer 1408. In such a case, the devices shown would be fabricated within the epi layer.

In some embodiments, the VBGR 1410 may extend all the way to the Deep HBGR layer 1408 independently of the Shallow HBGR layer 1406. Alternatively, a deep VBGR 1410 may extend sufficiently deep and connect to both the deep HBGR layer 1408 and the Shallow HBGR layer 1406. In some embodiments, the entire structure may be formed above an oxide or other dielectric layer (e.g., a SOI layer). The Deep HBGR layer 1408 would also preferably be formed above the SOI layer, whether or not top-side connected. In some embodiments, the Deep HBGR layer 1408 and the Shallow HBGR layer 1406 may overlap, as is shown in FIG. 17. In some embodiments, the Deep HBGR layer 1408 is not used, and only the Shallow HBGR layer 1406 is formed only beneath the P−well regions at a shallower depth than possible if it were also formed under the N−well regions.

### Bipolar BGR

In certain previous structures described above, a single P-type HBGR layer is formed beneath virtually the entire integrated circuit, or at least largely beneath an entire region of the integrated circuit that includes both NMOS and PMOS transistors. Referring now to FIG. 18, a P-type HBGR layer may be masked, or patterned, to extend only below the NFET transistor regions, and thus may be shallower than possible if it were also formed under the PFET (i.e., N−well) regions. FIG. 18 illustrates how a masked P-type HBGR would be used in a circuit, in this case an inverter. Here it is formed only in the P-type region below the NFET transistors. Because it does not exist below the N−wells, the P-type HBGR layer 1406 can be placed closer to the surface to provide more immediate protection from a particle strike. Another issue is that masked high-dose, high-energy implants used to form the BGR are more difficult to process. A shallower HBGR layer allows for a lower implant energy, partially offsetting the difficulty incurred by masking such an implant.

Simulations and measurements have shown that a HBGR layer implanted as a blanket layer extending laterally across the wafer and passing under N−well regions works very well at mitigating particle strikes that occur in, or cross through, the P−well regions. This is due to the fact that the BGR structure provides an extremely good contact to ground which, during a particle strike transient, prevents the P−well voltage from rising and therefore prevents forward-biasing any of the P-N junctions bounding the P−well region (such as P−well/N−well, or P−well/N+ source/drain junctions).

However, simulations and measurements have also shown that a blanket HBGR layer which is not electrically terminated either to the top side or back side increases the failure rate of a certain type when a strike hits an N−well region. When a particle strike transits through both the N−well and the HBGR layer, the N−well is then “shorted” to the P−well voltage, and this can interact with the N−well/P+ source/drain junction, and force the junctions into a forward bias condition. This effect can be avoided by patterning the P-type HBGR so that it does not extend below the N−well regions, because the geometric cross-section for particle strikes shorting N−wells to P-type HBGR layers is highly reduced.

The protection provided by the P-type BGR for strikes in the P−well, can also be provided for N−well strikes in a totally analogous (with opposite polarity) way by adding N-type BGR structures to the N−well regions. In FIG. 18, an N+ HBGR layer 1508 is disposed within the N−well region 1516, and is top-side connected by way of an N+ VBGR 1510. This provides a low-resistance path to the intended N−well voltage and thus prevents it from forward-biasing any of its adjacent P/N junctions. Such an N-type BGR structure is not required in all embodiments, but when utilized, the N-type HBGR layer 1508 in the N−well regions may be formed, for example, by implanting N-type doping ions at energy of 500 KeV to 1.2 MeV at a dose from 3e13 to 1e15 ions/cm².

By using these “bipolar BGR's,” both the N−wells and P−wells are prevented from straying very far from their intended voltages, and this prevents the various junctions from going into forward bias, and further prevents parasitic bipolar transistors from turning on and upsetting the device, or changing a memory state. This protection is probably reduced for high-angle strikes which have the potential to short the N−well 1516 or N-type HBGR layer 1508, to the adjacent P−well 1326 or P-type HBGR layer 1406. The geometric cross-section for this type of strike is small, but still nonzero. This cross-section can be further reduced by recessing the P-type HBGR's somewhat from the edges close to the N−wells, by recessing the N-type HBGR's from the edges close to the P−wells, or by adding extra distance between the N−wells and P−wells. Additional protection could also be obtained by using deep trenches between N−wells and P−wells (e.g., trench 1404 as shown) in addition to the shallow trenches.

### Segmented BGR

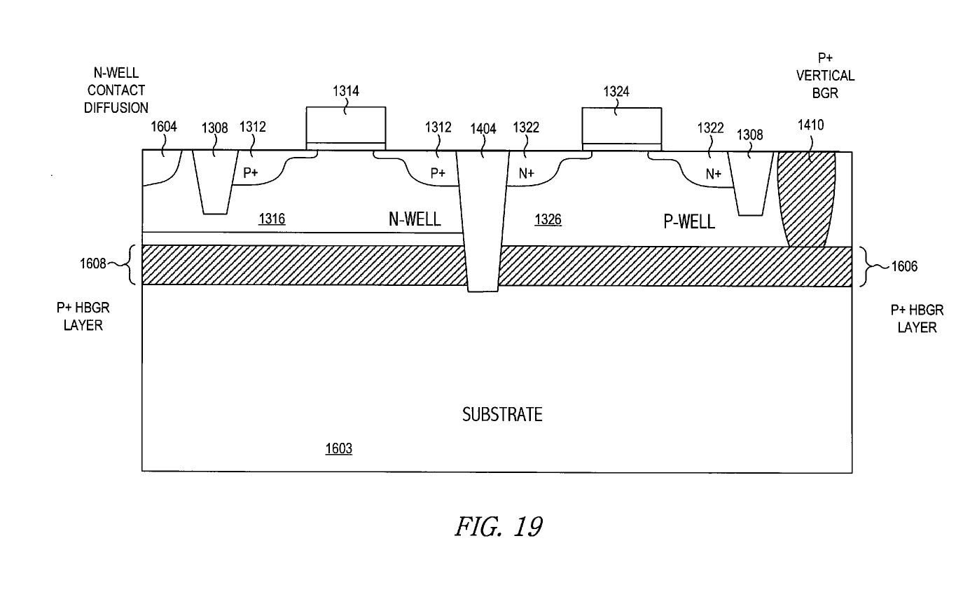

A segmented BGR embodiment is depicted in FIG. 19. This embodiment uses a P-type HBGR layer formed by implantation with an energy from 1.0 to 2.0 MeV and a dose from 3e13 to 5e15 ions/cm². The HBGR layer 1606 can be contacted either from the surface as shown (i.e., using P+ VBGR 1410), or from the bottom of the wafer, with or without a top-side contact. In this configuration, a deep isolation trench 1404 is formed to penetrate the HBGR layer and extend vertically into or below (e.g., greater than 5e17 ions/cm³) a substantial part of the Horizontal BGR layer 1606.

The purpose of the deep trench 1404 is to segment the HBGR layer such that the regions below N−wells do not have a continuous low-resistance path through the HBGR layer to a VBGR or to a contact, while the HBGR layer within regions below P−wells have a continuous path from the HBGR layer to the VGBR. This still provides the benefit of a good contact from the P−well to ground, but without also providing an undesirable path that can easily short the N−well to the HBGR when a strike passes through the N−well. This would lead to lowering of the N−well voltage, which would then trigger some of the parasitic junctions into forward bias. With this segmented structure, however, deep trenches can be formed surrounding the N−wells such that there is no easy path for current from the N−well to the VBGR contacts. By segmenting the HBGR layer by use of a deep trench, the resistance from the HBGR layer in a region below an N−well, to the HBGR layer in the region below a P−well or to a VBGR contact is increased by more than an order-of-magnitude. This ensures that the N−wells remain substantially at their original applied voltage during a strike, thus preventing upset.

With present technology, shallow trenches 1308 are still useful to allow for contacts to the P−wells while still maintaining compact MOS device structures. In a preferred embodiment a BGR structure is combined with a process that includes trenches with two different depths: one more shallow than the HBGR layer, and the other deeper than the HBGR layer. More specifically, the shallow trench would preferably be at a depth that is shallower than most of the dopant in the HBGR layer, and the deep trench would preferably be at a depth that is greater than a large majority of the dopant in the HBGR layer. In some embodiments, more than two trench depths may be used.

In certain embodiments, if the device layout can so provide, all or most N−well regions are surrounded by a deep trench. Alternatively, a deep trench could be placed exclusively or mainly along the N−well/P−well boundaries and also work well. In a similar fashion, there are many other possible layout variations that can provide some degree of trench isolation to increase the resistance of the circuit to strikes.

Another embodiment includes an HBGR layer with only the deep trench 1404 (and no shallow trenches 1308). This would require an additional innovative way of contacting the P−well to a contact somehow without ruining the transistor device structures. One possibility would be to combine the P-source/drain contacts with a VBGR structure.

As used herein, a “layer” need not extend fully across a die or across a wafer. As used herein, a substrate includes a top surface upon which useful circuit structures for a semiconductor device are fabricated, and includes a bottom surface upon which supports the device, and which is usually attached to a package. This bottom surface is also described herein as the “backside” of the substrate or wafer. Unless the context requires otherwise, a substrate described herein may include a starting wafer (or other substrate material) and an epitaxial layer formed thereupon. The term “package” should not be viewed in a restrictive manner, as it is intended to encompass dual-in-line packages (DIPs), single-in-line packages (SIPs), small outline (SO) packages, plastic encapsulated packaging techniques of many different form factors, ceramic packages, chip-on-board assembly techniques, multi-chip modules, and any other technique providing a surface to which a semiconductor device may be mounted or attached.

Many of the embodiments described herein advantageously achieve a lower resistance between the HBGR layer and the backside of the substrate than between the HBGR layer and the top surface of the substrate. Preferably the ratio between these resistances is 1:5, and more preferably the ratio is 1:8, and even more preferably the ratio is 1:10. Similar ratios are advantageous when viewing the relative doping concentration between a heavily doped starting wafer and a lightly doped epi layer. Preferably the doping concentration between the HBGR layer and the backside contact is at least 1e18 ions/cm³, and more preferably is at least 1e19 ions/cm³.

Regarding terminology used herein, it will be appreciated by one skilled in the art that any of several expressions may be equally well used when describing the operation of a circuit including the various signals and nodes within the circuit. Any kind of signal, whether a logic signal or a more general analog signal, takes the physical form of a voltage level (or for some circuit technologies, a current level) of a node within the circuit. Such shorthand phrases for describing circuit operation used herein are more efficient to communicate details of circuit operation, particularly because the schematic diagrams in the figures clearly associate various signal names with the corresponding circuit blocks and nodes.

An insulated gate field effect transistor (IGFET) may be conceptualized as having a control terminal which controls the flow of current between a first current handling terminal and a second current handling terminal. Although IGFET transistors are frequently discussed as having a drain, a gate, and a source, in most such devices the drain is interchangeable with the source. This is because the layout and semiconductor processing of the transistor is frequently symmetrical (which is typically not the case for bipolar transistors). For an N-channel IGFET transistor, the current handling terminal normally residing at the higher voltage is customarily called the drain. The current handling terminal normally residing at the lower voltage is customarily called the source. A sufficient voltage on the gate (relative to the source voltage) causes a current to therefore flow from the drain to the source. The source voltage referred to in N-channel IGFET device equations merely refers to whichever drain or source terminal has the lower voltage at any given point in time. For example, the “source” of the N-channel device of a bi-directional CMOS transfer gate depends on which side of the transfer gate is at the lower voltage. To reflect this symmetry of most N-channel IGFET transistors, the control terminal may be deemed the gate, the first current handling terminal may be termed the “drain/source”, and the second current handling terminal may be termed the “source/drain”. Such a description is equally valid for a P-channel IGFET transistor, since the polarity between drain and source voltages, and the direction of current flow between drain and source, is not implied by such terminology. Alternatively, one current-handling terminal may arbitrarily deemed the “drain” and the other deemed the “source”, with an implicit understanding that the two are not distinct, but interchangeable. It should be noted that IGFET transistors are commonly referred to as MOSFET transistors (which literally is an acronym for “Metal-Oxide-Semiconductor Field Effect Transistor”), even though the gate material may be polysilicon or some material other than metal, and the dielectric may be oxynitride, nitride, or some material other than oxide. The casual use of such historical legacy terms as MOS and MOSFET should not only be interpreted to literally specify a metal gate FET having an oxide dielectric.

Regarding power supplies, a single positive power supply voltage (e.g., a 1.5 volt power supply) used to power a circuit is frequently named the “V_{DD}” power supply. In an integrated circuit, transistors and other circuit elements are actually connected to a V_{DD} terminal or a V_{DD} node, which is then operably connected to the V_{DD} power supply. The colloquial use of phrases such as “tied to V_{DD}” or “connected to V_{DD}” is understood to mean “connected to the V_{DD} node”, which is typically then operably connected to actually receive the V_{DD} power supply voltage during use of the integrated circuit. The reference voltage for such a single power supply circuit is frequently called “V_{SS}.” Transistors and other circuit elements are actually connected to a V_{SS} terminal or a V_{SS} node, which is then operably connected to the V_{SS} power supply during use of the integrated circuit. Frequently the V_{SS} terminal is connected to a ground reference potential, or just “ground.” Generalizing somewhat, the first power supply terminal is frequently named “V_{DD}”, and the second power supply terminal is frequently named “V_{SS}.” Historically the nomenclature “V_{DD}” implied a DC voltage connected to the drain terminal of an MOS transistor and V_{SS} implied a DC voltage connected to the source terminal of an MOS transistor. For example, old PMOS circuits used a negative V_{DD} power supply, while old NMOS circuits used a positive V_{DD} power supply. Common usage, however, frequently ignores this legacy and uses V_{DD} for the more positive supply voltage and V_{SS} for the more negative (or ground) supply voltage unless, of course, defined otherwise. Describing a circuit as functioning with a “V_{DD} supply” and “ground” does not necessarily mean the circuit cannot function using other power supply potentials. Other common power supply terminal names are “V_{CC}” (a historical term from bipolar circuits and frequently synonymous with a +5 volt power supply voltage, even when used with MOS transistors which lack collector terminals) and “GND” or just “ground.”

Moreover, implementation of the disclosed devices and techniques is not limited by CMOS technology, and thus implementations can utilize NMOS, PMOS, and various bipolar or other semiconductor fabrication technologies. While the disclosed devices and techniques have been described in light of the embodiments discussed above, one skilled in the art will also recognize that certain substitutions may be easily made in the circuits without departing from the teachings of this disclosure. Also, many circuits using NMOS transistors may be implemented using PMOS transistors instead, as is well known in the art, provided the logic polarity and power supply potentials are reversed. In this vein, the transistor conductivity type (i.e., N-channel or P-channel) within a CMOS circuit may be frequently reversed while still preserving similar or analogous operation. Moreover, other combinations of output stages are possible to achieve similar functionality.

While circuits and physical structures are generally presumed, it is well recognized that in modem semiconductor design and fabrication, physical structures and circuits may be embodied in computer readable descriptive form suitable for use in subsequent design, test or fabrication stages as well as in resultant fabricated semiconductor integrated circuits. Accordingly, claims directed to traditional circuits or structures may, consistent with particular language thereof, read upon computer readable encodings and representations of same, whether embodied in media or combined with suitable reader facilities to allow fabrication, test, or design refinement of the corresponding circuits and/or structures. The invention is contemplated to include circuits, related methods or operation, related methods for making such circuits, and computer-readable medium encodings of such circuits and methods, all as described herein, and as defined in the appended claims. As used herein, a computer-readable medium may include a storage medium such as a disk, tape, or other magnetic, optical, semiconductor (e.g., flash memory cards, ROM), or electronic medium. A computer-readable medium may also include a transiently encoded form suitable for transmission via a network, wireline, wireless, or other communications medium. An encoding of a circuit may include circuit schematic information, physical layout information, behavioral simulation information, and/or may include any other encoding from which the circuit may be represented or communicated.

The foregoing details description has described only a few of the many possible implementations of the present invention. For this reason, this detailed description is intended by way of illustration, and not by way of limitations. Variations and modifications of the embodiments disclosed herein may be made based on the description set forth herein, without departing from the scope and spirit of the invention. It is only the following claims, including all equivalents, that are intended to define the scope of this invention. Moreover, the embodiments described above are specifically contemplated to be used alone as well as in various combinations. Accordingly, other embodiments, variations, and improvements not described herein are not necessarily excluded from the scope of the invention.

What is claimed is:

1. A method for manufacturing a CMOS integrated circuit product to achieve improved radiation hardness of said integrated circuit product, said method comprising:
forming NMOS and PMOS transistors on a semiconductor substrate;
forming a horizontal buried guard ring (HBGR) layer beneath at least a some of the transistors and within the semiconductor substrate;
providing an electrical connection from a backside of the semiconductor substrate to the HBGR layer, to provide an electrical connection, when packaged, from the HBGR layer to a suitable well voltage of said integrated circuit.

2. The method as recited in claim 1 wherein the HBGR layer is disposed beneath at least some PMOS transistors.

3. The method as recited in claim 2 wherein the HBGR layer is disposed beneath at least some NMOS transistors.

4. The method as recited in claim 1 wherein the suitable well voltage is ground.

5. The method as recited in claim 1 further comprising:
forming a lightly-doped P-type epitaxial layer upon a heavily-doped P-type substrate; and
forming the NMOS and PMOS transistors generally at an upper surface of the epitaxial layer.

6. The method as recited in claim 5 further comprising:
forming the HBGR layer at least partially within the heavily-doped P-type substrate.

7. The method as recited in claim 1 further comprising:
lapping a semiconductor wafer including said circuit die before singularization of individual circuit dies.

8. The method as recited in claim 7 further comprising:
forming a conductive layer on the backside of the wafer after said lapping, and before said singularization of individual circuit dies.

9. The method as recited in claim 8 further comprising:
attaching the integrated circuit die to the package conductive pad using a solder.

10. The method as recited in claim 7 further comprising:
attaching the integrated circuit die to the package conductive pad using an electrically conductive adhesive.

11. A semiconductor device comprising:
a substrate having a first conductivity type and having a top surface and a bottom surface;
a first well having the first conductivity type formed at the top surface of the substrate;
a horizontal buried guard ring layer having the first conductivity type and located beneath the first well; and
wherein the substrate includes a back side contact on the bottom surface, and provides a lower resistance from the buried guard ring layer to the back side contact than from the buried guard ring layer through the first well to the top surface.

12. The device as recited in claim 11 wherein the substrate is heavily-doped P-type in a region below the buried guard ring layer, and lightly-doped P-type in a region above the buried guard ring layer.

13. The device as recited in claim 12 wherein the doping concentration in the region below the buried guard ring layer is at least five times greater than the doping concentration in the region above the buried guard ring layer.

14. The device as recited in claim 11 wherein:
the buried guard ring layer extends substantially continuously beneath both NMOS and PMOS transistors.

15. The device as recited in claim 11 wherein the substrate further comprises:
a substrate material; and
an epitaxial layer of semiconductor material formed on the substrate material;
wherein the epitaxial layer of semiconductor material has the first substrate impurity concentration, and wherein at least one of the first well and the buried guard ring layer are at least partially disposed in the epitaxial layer of semiconductor material.

16. A semiconductor device comprising a substrate having an implanted horizontal buried guard ring (HBGR) layer formed below a transistor of a first conductivity type, said substrate providing a resistance between said HBGR layer and a backside surface of the substrate that is lower than a resistance between the HBGR layer and a top surface of the substrate.

17. The device as recited in claim 16 wherein:
the resistance between said HBGR layer and the backside surface of the substrate results from a P+ starting wafer; and
the resistance between the HBGR layer and the top surface of the substrate results from a grown P− epitaxial layer.

18. The device as recited in claim 17 wherein the resistance between said HBGR layer and the backside surface of the substrate is less than 1000 ohms.

19. The device as recited in claim 17 wherein the doping concentration in the P+ starting wafer is at least five times greater than the doping concentration in the grown P− epitaxial layer.

20. The device as recited in claim 16 wherein:
the HBGR layer is also formed below a transistor of a second conductivity type opposite the first conductivity type, and at a sufficient depth to avoid noticeably counter-doping a device well of opposite conductivity type as the HBGR layer.

21. The device as recited in claim 16 wherein:
the backside surface includes a deposited conductive layer to reduce contact resistance to the semiconductor substrate.

22. A semiconductor device comprising:
a substrate having a top surface and a bottom surface, and having a first conductivity type for at least a portion thereof adjacent the bottom surface;
NMOS and PMOS transistors formed generally at the top surface;
a horizontal buried guard ring (HBGR) layer having the first conductivity type, formed within the substrate and beneath at least some of the transistors; and
wherein the substrate is more heavily-doped between the HBGR layer and the bottom surface than between the HBGR layer and the top surface.

23. The device as recited in claim 22 wherein:
the substrate region between said HBGR layer and the bottom surface of the substrate comprises a P+ starting wafer; and
the substrate region between the HBGR layer and the top surface of the substrate comprises a grown P− epitaxial layer.

24. The device as recited in claim 23 wherein the peak doping concentration in the HBGR layer is greater than the background doping concentration of the substrate below the HBGR layer.

25. The device as recited in claim 24 wherein the background doping concentration of the substrate below the HBGR layer is greater than 1e18 ions/cm³.

26. The device as recited in claim 22 embodied in computer readable media for suitable for design or fabrication of the device.

27. A packaged integrated circuit comprising:
a semiconductor die having a horizontal buried guard ring (HBGR) layer formed below at least one N−well and at least one P−well, and further having a conductive path from the HBGR layer to a backside surface of the die; and
a package having a conductive pad upon which the semiconductor die is attached, and further providing a connection from the pad to an external terminal of said package.

28. The packaged integrated circuit as recited in claim 27 wherein the semiconductor die comprises:
a heavily-doped P-type substrate upon which a lightly-doped p-type epitaxial layer is formed.

29. The device as recited in claim 27 wherein:
the HBGR layer is at least partially formed within the heavily-doped P-type substrate.

30. The device as recited in claim 27 wherein:
the semiconductor die is attached to the conductive pad using an electrically conductive adhesive.

31. The device as recited in claim 30 wherein:
the semiconductor die comprises a backside metal layer.
